(19) United States
(12) Patent Application Publication
(10) Pub. No.: US 2026/0319005 A1
(43) Pub. Date: Oct. 15, 2026

(54) METHOD AND SYSTEM FOR GENERATING AN EXCITATION SIGNAL FOR ELECTROCHEMICAL IMPEDANCE SPECTROSCOPY

(71) Applicants: Weiyu TAI, HUAIAN CITY (CN); Ruian TAN, Shanghai (CN); Junhua YAN, Shanghai (CN); Jiemo ZHU, NANTONG (CN)

(72) Inventors: Weiyu TAI, HUAIAN CITY (CN); Ruian TAN, Shanghai (CN); Junhua YAN, Shanghai (CN); Jiemo ZHU, NANTONG (CN)

(21) Appl. No.: 19/464,798

(22) Filed: Jan. 30, 2026

Related U.S. Application Data
(63) Continuation-in-part of application No. 19/406,836, filed on Dec. 2, 2025.
(60) Provisional application No. 63/727,264, filed on Dec. 3, 2024.

(51) Int. Cl. G01R 31/389; G01R 31/36; G01R 31/364; H01M 10/48

(52) U.S. Cl. CPC G01R 31/389; G01R 31/364; G01R 31/3644; H01M 10/482

(57) ABSTRACT

A system includes a bus, a primary coil, and a first circuit coupled between the bus and the primary coil. A first secondary coil is DC-isolated from the primary coil. A second secondary coil is DC-isolated from the primary coil. The system also includes first and second battery terminals. A second circuit is coupled between the first secondary coil and the first battery terminals. A third circuit is coupled between the second secondary coil and the second battery terminals. A controller is coupled to the first circuit, the second circuit, and the third circuit. The controller is configurable control at least two of the first circuit, the second circuit, and the third circuit to transfer energy either from the first secondary coil to the primary coil and then from the primary coil to the second secondary coil, or from the first secondary coil directly to the second secondary coil.

### CROSS-REFERENCE TO RELATED APPLICATIONS

This application is a continuation-in-part of U.S. application Ser. No. 19/406,836, filed Dec. 2, 2025, entitled METHOD AND SYSTEM FOR ACTIVE BATTERY PACK BALANCING, which claims priority to U.S. Provisional Application No. 63/727,264, filed Dec. 3, 2024, entitled “ESS ACTIVE PACK BALANCE SYSTEM,” each of which is hereby incorporated herein by reference in its entirety.

### BACKGROUND

Various energy storage systems (ESS) may contain multiple energy-storage cells, such as battery cells, connected in series to form battery packs or modules. Energy storage systems including multiple battery packs can be part of an energy storage infrastructure or can be part of a mobile energy storage system (e.g., part of an electric vehicle). Due to internal factors (e.g., cell impedance or aging) and external factors (e.g., temperature gradients), the capacity or state of charge (SOC) of individual packs or modules can differ. These variations can lead to uneven charging and discharging behavior within the series stack, resulting in SOC imbalances that reduce usable energy capacity and may impact system performance and longevity.

### SUMMARY

In one example, a system includes a bus, a primary coil, and a first circuit coupled between the bus and the primary coil. A first secondary coil is DC-isolated from the primary coil. A second secondary coil is DC-isolated from the primary coil. The system also includes first and second battery terminals. A second circuit is coupled between the first secondary coil and the first battery terminals. A third circuit is coupled between the second secondary coil and the second battery terminals. A controller is coupled to the first circuit, the second circuit, and the third circuit. The controller is configurable control at least two of the first circuit, the second circuit, and the third circuit to transfer energy either from the first secondary coil to the primary coil and then from the primary coil to the second secondary coil, or from the first secondary coil directly to the second secondary coil.

In another example, a system includes a bus, a bidirectional isolated DC-DC converter, and an energy storage element. The isolated DC-DC converter includes a primary coil and a first circuit coupled between the bus and the primary coil. A first secondary coil is magnetically coupled to the primary coil and a second secondary coil is magnetically coupled to the primary coil and the first secondary coil. A second circuit is coupled between the first secondary coil and first and second battery terminals and a third circuit is coupled between the second secondary coil and third and fourth battery terminals. An energy storage element includes a plurality of battery cells, in which a first portion of the plurality of battery cells is coupled between the first and second battery terminals and a second portion of the plurality of battery cells is coupled between the third and fourth battery terminals. A controller is coupled to the bidirectional isolated converter and configurable to control the converter circuit to provide an alternating-current (AC) excitation current signal to the plurality of battery cells based on a voltage induced on at least one of the first secondary coil and the second secondary coil.

In yet another example, a method includes inducing a voltage at a secondary coil of a bidirectional isolated DC-DC converter. The method may also include providing, by the secondary coil responsive to the induced voltage, an excitation current to a battery pack coupled to the secondary coil. The method may also include measuring a voltage of at least one battery cell of the battery pack responsive to the excitation current. The method may also include measuring the excitation current. The method may also include determining an electrical impedance of the at least one battery cell responsive to measuring the voltage and measuring the excitation current.

In yet another example, a method includes transferring energy either from a first secondary coil of a bidirectional isolated DC-DC converter, which is coupled between a bus and battery terminals, to a primary coil of the bidirectional isolated DC-DC converter and from the primary coil to a second secondary coil. The method may also include transferring energy from the first secondary coil directly to the second secondary coil. The bidirectional isolated DC-DC converter includes the primary coil, the first secondary coil, and the second secondary coil. A first circuit is coupled between the first secondary coil and first battery terminals of the battery terminals and a second circuit is coupled between the second secondary coil and second battery terminals of the battery terminals. The primary coil is DC-isolated from the first secondary coil and the second secondary coil. The energy is transferred based on controlling the first circuit and the second circuit.

### BRIEF DESCRIPTION OF THE DRAWINGS

FIG. 1 is a schematic diagram illustrating a system for performing active pack balancing (APB) and/or electrochemical impedance spectroscopy (EIS) operations, according to various examples.

FIG. 2 is a schematic diagram illustrating an example of a bidirectional isolated DC-DC converter that may be implemented for performing active pack balancing operations, according to various examples.

FIG. 3 includes graphs showing a charging operation of a battery pack using the circuit of FIG. 2, according to various examples.

FIGS. 4A and 4B are schematic diagrams illustrating an ESS including one or more bidirectional isolated DC-DC converters, according to various examples.

FIG. 5 is a flow diagram showing a method of performing an active pack balancing operation, according to various examples.

FIG. 6 is a schematic diagram illustrating the signal flow of the active pack balancing operation of FIG. 5, according to various examples.

FIG. 7 is a schematic diagram illustrating charging and discharging operations of battery packs as part of an active pack balancing operation, according to various examples.

FIGS. 8, 9, and 10 include graphs illustrating current and voltage waveforms for current regulation operations during implementing an active pack balancing operation, according to various examples.

FIG. 11 is a flow diagram illustrating a method of performing an electrochemical impedance spectroscopy operation, according to various examples.

FIG. 12 is a schematic diagram illustrating the signal flow of the electrochemical impedance spectroscopy operation of FIG. 11, according to various examples.

FIG. 13 includes graphs showing illustrating voltage and current waveforms for performing electrochemical impedance spectroscopy in the isolated DC-DC converter shown in FIGS. 4A and 4B, according to various examples.

FIG. 14 includes graphs showing zoomed-in version of the graphs of FIG. 13.

FIG. 15 is a schematic diagram illustrating the signal flow in an ESS for combined active pack balancing and electrochemical impedance spectroscopy operations of FIGS. 5 and 11, according to various examples.

FIG. 16 is a schematic diagram of a voltage measurement circuit and a current monitoring circuit that may be implemented for performing electrochemical impedance spectroscopy, according to various examples.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

This disclosure relates to various methods and systems for performing active balancing of energy storage elements, such as battery packs, in an energy storage system (ESS).

As an example, an ESS includes one or more bidirectional isolated DC-DC converters. The one or more isolated DC-DC converters are coupled between a bus (e.g., a voltage bus) and a first battery terminal of a respective energy storage element, such as a battery pack. The battery pack includes a plurality of battery cells coupled between the first battery terminal and a second battery terminal. The battery cells of the battery pack may be connected in series between the first and second battery terminals.

As a further example, an isolated DC-DC converter includes a primary-side circuit, a secondary-side circuit, and a bidirectional isolation circuit (e.g., a transformer), in which the primary-side circuit is coupled to the secondary-side circuit through the bidirectional isolation circuit to provide a galvanic isolation (or DC isolation) between primary and secondary-side circuits of the isolated DC-DC converter. The transformer includes a primary coil that is magnetically coupled to one or more secondary coils. The primary-side circuit is coupled between the primary coil and the bus, and the secondary-side circuit is coupled between a secondary coil and the battery terminal. Additionally, or alternatively, the primary and second circuits of the isolated DC-DC converter include respective bridge circuits, such as a half bridge or full bridge, which may depend on expected current amplitude through the primary and secondary-side circuits. A controller, which is coupled to one or more isolated DC-DC converters, may control each isolated DC-DC converter to transfer energy to or from the voltage bus and/or to or from a respective battery pack, to which the respective isolated DC-DC converter is coupled. As described herein, the direction and magnitude of energy being transferred through each isolated DC-DC converter may vary depending on how energy is being transferred through one or more isolated DC-DC converters, such as for performing APB and/or EIS operations.

As an example, for performing an EIS operation, the ESS includes one or more isolated DC-DC converters having secondary-side circuits. The controller, operating in an EIS mode, controls one or more secondary-side circuits of the one or more isolated DC-DC converters to provide an alternating-current (AC) excitation current signal to a battery terminal based on a voltage induced (e.g., via magnetic coupling) at the secondary coil to which the secondary-side circuit is coupled. The controller may control the secondary-side circuit to vary the frequency of the AC excitation current signal over a range of frequencies suitable for performing an EIS operation on one or more battery cells. In one example, the voltage is induced at the secondary coil by the primary coil of the DC-DC converter (e.g., based on the controller controlling the primary-side circuit). In another example, where the DC-DC converter includes at least first and second secondary coils and respective first and second secondary-side circuits, the voltage may be induced at the first secondary coil by the second secondary coil (e.g., based on the controller controlling the second secondary-side circuit). While the voltage is induced at the first secondary coil, the primary-side circuit may be turned off (e.g., be disabled) to facilitate energy transfer directly between the first and second secondary coils. The ESS further may include a measurement circuit, which is coupled to one or more battery cells of the battery pack, to measure an electrical impedance of the battery cell(s) based on the AC excitation current signal. For example, the measurement circuit includes a voltage sensing circuit (e.g., voltmeter) to measure the voltage across the battery cell(s). The measurement circuit may also include a current monitor circuit to measure the AC excitation current signal through the battery cell(s), based on which the electrical impedance of the battery cell(s) is determined (e.g., by the controller).

Performing EIS in an ESS with bidirectional isolated DC-DC converters can provide various advantages. Specifically, when generating the excitation current signal for battery cells of a respective battery pack directly between the first and second secondary coils, the ESS can perform other operations with respect to one or more other battery packs, which may include normal operation, EIS operation, and/or APB operation. Additionally, such arrangements can leverage the existing bidirectional isolated DC-DC converter(s) and voltage bus that are already part of the ESS to perform EIS and other operations, which can reduce cost. Moreover, because the isolated DC-DC converter is used to provide the excitation current rather than a standalone signal generator, an increased current magnitude may be utilized for performing EIS operations.

As another example, for performing an APB operation, the ESS includes at least first and second isolated DC-DC converters. The first isolated DC-DC converter is coupled between the bus (e.g., voltage bus) and a first battery pack and the second isolated DC-DC converter is coupled between the voltage bus and a second battery pack. The controller, operating in an APB mode, controls first and second isolated DC-DC converters to perform APB. In an example where a second battery pack has a pack voltage that is greater than the pack voltage of the first battery pack, the controller controls the first isolated DC-DC converter to provide a regulated current signal (e.g., a substantially constant—or regulated—current) to charge the first battery pack based on the bus voltage. The controller also controls the second isolated DC-DC converter to provide a voltage (e.g., a substantially constant—or regulated—voltage) to the voltage bus by discharging the second battery pack. Advantageously, when implementing APB, the voltage provided by the second isolated DC-DC converter to the voltage bus can help to stabilize the voltage bus, which would otherwise fluctuate responsive to energy used by the first isolated DC-DC converter for charging the first battery pack. The controller may implement APB to charge the first battery pack and discharge the second battery pack until balance has been achieved (e.g., until the respective voltages of the first and second battery packs are approximately the same).

As further described herein, an ESS may implement EIS on one or more battery packs and then implement APB on the same one or more battery packs. Alternatively, EIS and APB may be implemented concurrently on different battery packs. In some examples, the controller controls one or more DC-DC converters (e.g., concurrently or sequentially) to operate in an EIS mode and provide an AC excitation current signal, while two or more other DC-DC converters are controlled operate (e.g., concurrently) in an APB mode to perform APB with respect to one or more other battery packs.

Performing APB in an ESS with bidirectional isolated DC-DC converters can provide various advantages. Specifically, without balancing, the pack with lowest SOC may limit the overall capacity of all of the battery packs, as well as life and utilization of individual battery packs especially in a case where the battery packs are connected in series to expand the capacity. Balancing can improve the SOC balance of each battery pack. Active pack balancing can achieve SOC balance by moving charge from one battery pack to another, instead of dissipating the charge to ground as in passive pack balancing, which can avoid the thermal management, weak balance capacity, as well as waste of charge issues associated with passive pack balancing. As described herein, bidirectional isolated DC-DC converters, such as a dual-bridge series resonant converter, are provided to perform APB, where the voltage bus can be used to discharge the high voltage battery pack and charge low voltage battery pack. Such arrangements can leverage the existing bidirectional isolated DC-DC converter(s) and voltage bus that is already part of the ESS to perform APB, which can reduce cost. The converter topology described herein further may be used in non-APB and/or non-EIS operations, such as normal energy storage and discharging operation. Moreover, the isolated DC-DC converter can be controlled using phase shift control to control flow of charge from one battery pack to another through the voltage bus by phase shift control, which can simplify control of the APB operation. All these can improve the overall performance of the ESS and can be achieved at reduced cost.

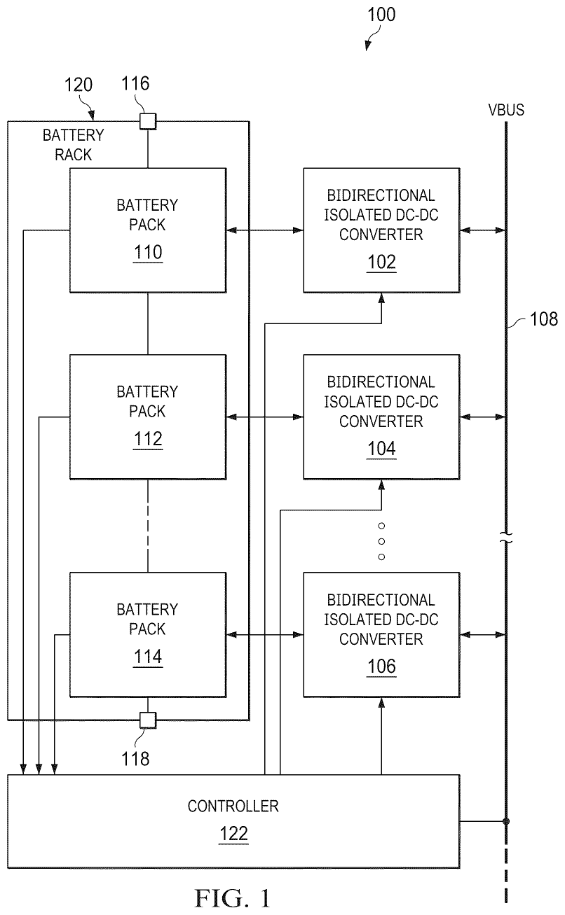

FIG. 1 is a block diagram illustrating an example of a system 100, such as an energy storage system (ESS). The system 100 includes a plurality of bidirectional isolated DC-DC converters 102, 104, and 106. The system 100 may include any number of isolated DC-DC converters 102, 104, and 106. Each of the isolated DC-DC converters 102, 104, and 106 may be implemented according to virtually any isolated converter topology, which can vary according to application requirements for a given operating environment. In examples described herein, the isolated DC-DC converters 102, 104, and 106 include an isolation structure, such as primary and secondary coils, coupled between respective primary- and secondary-side circuits, where the primary and secondary coils are DC isolated from each other, but the primary and secondary coils can transmit signals, including power, via magnetically coupling between the coils. Also, or alternatively, as disclosed herein, each of the isolated DC-DC converters 102, 104, and 106 may include one primary coil and one or more secondary coils. Other types of isolation structures are possible between primary- and secondary-side circuits.

In the example of FIG. 1, each of the isolated DC-DC converters 102, 104, and 106 is coupled between a bus 108 (e.g., a voltage bus) and a respective battery pack 110, 112, and 114. The bus 108 provides a bus voltage (labelled VBUS) to the system 100, such as a regulated DC voltage. In some examples, the bus voltage VBUS may be provided by another power supply (not shown), which may include one or more other power converters to convert another voltage, which may be an AC or DC voltage, to the voltage VBUS. As one example, VBUS may be 24 V. Other voltages are possible for VBUS in other examples.

As shown in FIG. 1, the battery packs 110, 112, and 114 are connected in series between terminals 116 and 118 of a battery rack 120 (or another battery support structure holding multiple battery cells). Each battery pack 110, 112, and 114 includes a plurality of series-connected battery cells. Each isolated DC-DC converter 102, 104, and 106 is coupled to one or more battery terminals of a respective battery pack 110, 112, and 114. In some example embodiments, the battery cells of one or more battery packs 110, 112, and 114 may be divided into modules (also referred to herein as battery modules), in which each module of a given battery pack includes a portion (e.g., approximately half) of the battery cells for the given battery pack. The isolated DC-DC converter 102, 104, and 106 that is coupled to the given battery pack 110, 112, and 114 may include separate connections to battery terminals of the modules for transferring energy (e.g., sourcing or sinking current) to and from each respective module of the given battery pack. The battery packs 110, 112, and 114 may be divided into modules having other fractional portions of battery cells.

The system 100 also includes one or more controllers 122 having control outputs coupled to respective control inputs of each of the isolated DC-DC converters 102, 104, and 106. Each isolated DC-DC converter 102, 104, and 106 may have a dedicated controller 122 to control each isolated DC-DC converter or, in other examples, a given controller may control multiple isolated DC-DC converters. The controller 122 also includes inputs coupled to respective outputs of each of the battery packs 110, 112, and 114. The controller 122 may also include a terminal coupled to the bus 108 to receive the bus voltage VBUS for powering the controller. A voltage measurement circuit (not shown), which may be implemented within or external to the controller, may measure the voltage VBUS at the terminal for use in controlling one or more of the isolated DC-DC converters 102, 104, and 106. The controller 122 may be implemented as a microcontroller (or microcontroller unit) in an integrated circuit (IC) that includes one or more processors, memory, and input/output (I/O) peripherals that cooperate to perform the functions described herein. Alternatively, or additionally, the controller 122 may be implemented as or include one or more of an application-specific integrated circuit (ASIC), a field-programmable gate array (FPGA), or equivalent discrete and/or integrated logic circuitry.

In operation, the controller 122 may control one or more of the isolated DC-DC converters 102, 104, and 106 to transfer power from bus 108 (which receives power from another power source, such as AC grid or a DC source) to charge the battery packs and store energy in the battery pack. The controller 122 may control one or more of the isolated DC-DC converters 102, 104, and 106 to discharge the battery packs to release power to bus 108, which can then transfer the power to a load (which can include the AC grid or another DC power sink, such as a battery).

The controller 122 may also operate in an APB mode and control one or more of the isolated DC-DC converters 102, 104, and 106 to transfer energy between respective battery packs 110, 112, and 114 via the voltage bus. For example, the controller 122 receives information (e.g., from voltage sensors) about the voltages across each of the battery packs 110, 112, and 114 to determine if APB is needed. The controller 122 further identifies which of the battery packs 110, 112, and 114 has the highest pack voltage and which battery pack has the lowest pack voltage. In a first example, the controller determines that battery pack 112 has the highest pack voltage of the rack and battery pack 110 has the lowest pack voltage. The controller may also determine (e.g., via pre-programming, sensing, etc.) that the isolated DC-DC converter 102 is coupled to battery pack 110 and isolated DC-DC converter 104 is coupled to battery pack 112. The controller 122 may then control the identified pair of isolated DC-DC converters 102 and 104, and 106 to perform an APB operation when operating in the APB mode. For example, the controller 122 controls isolated DC-DC converter 102 to provide a current signal to a respective terminal to charge the first battery pack 110 based on VBUS, and the controller controls isolated DC-DC converter 104 to provide a voltage (e.g., a regulated voltage) to the bus 108 by discharging from the second battery pack 112. In this way, the voltage of the highest voltage battery pack 112 may decrease based on its discharging while the voltage of the lowest voltage battery pack 110 may increase based on its charging. Additionally, the isolated DC-DC converter 102 may provide the voltage to the bus 108 during the APB mode to stabilize VBUS, as VBUS tends to reduce responsive to the energy utilized by the isolated DC-DC converter 102 charging its battery pack 110. In some examples, the voltage provided by isolated DC-DC converter 102 may supply sufficient energy to enable one or more additional isolated DC-DC converters (e.g., isolated DC-DC converter 106) to also charge battery packs during the APB mode. The controller 122 may control the isolated DC-DC converters 102 and 104 to continue the APB mode until balance is reached between the battery packs 110 and 112 (e.g., to within a voltage threshold). More than one pair of isolated DC-DC converters may be controlled to perform APB concurrently or sequentially.

Additionally, battery cells (e.g., battery cells of battery packs 110, 112, and 114), and battery racks (e.g., battery rack 120) may exhibit variances caused by, for example, manufacturing variances, assembly variances, cell aging, etc. Therefore, each battery pack 110, 112, and 114 of battery rack 120 may have a different state of charge. For example, cell capacity continues to increase (e.g., from 10 Ah to 280 Ah, to 314 Ah, to 560 Ah, etc.). The battery life for an ESS may be 10 years or more. Battery rack 120 may include a mix between old and new battery packs 110, 112, and 114, which may result in some battery packs having different capacities, which may result in inconsistent state of charge for each battery pack. The battery pack 110, 112, and 114 with the lowest state of charge may limit the capacity of battery rack 120, which may affect the utilization and life of the battery rack 120. APB may improve the lifetime of the battery packs 110, 112, and 114 of the battery rack 120. Moreover, by discharging battery packs exhibiting higher voltages and charging battery packs exhibiting low voltages, as disclosed herein, APB further may advantageously result in increased power efficiency of the system 100 with high balance capacity, and low maintenance (e.g., advantageously avoiding manual labor costs), without wasting energy (e.g., which may advantageously result in better thermal management), and without reducing the overall capacity of the battery rack.

In addition, or as an alternative to APB, it may be advantageous to utilize the system 100 to perform EIS to ascertain or predict one or more parameters (e.g., properties or conditions) of battery cells in one or more of the battery packs 110, 112, and 114. For example, the battery parameters may be characterized by the level of available charge, such as a state of charge (SOC), and the percentage of useful charge/discharge cycles that remain, such as a state of health (SOH). The battery impedance spectrum, which is the ratio between the battery cell voltage and current in the frequency domain, has a strong correlation to battery SOC, SOH, and internal temperature. As disclosed herein, the controller 122 may measure the impedance spectra of one or more battery cells, which, in turn, may be used to determine the SOC, SOH, temperature, and/or other battery parameters.

As disclosed herein, the controller 122 may operate in an EIS mode, in which the controller controls one or more of the isolated DC-DC converters 102, 104, and 106 to transfer energy to or within a respective battery pack 110, 112, and 114. The controller can determine electrical impedance (or impedance spectra) of one or more battery cells based on voltage and current measurements during the energy transfer. For example, during EIS, the controller 122 controls one or more of the isolated DC-DC converters 102, 104, and 106 to provide an AC excitation signal (a current signal or a voltage signal) to one or more battery packs battery pack 110, 112, and 114. The AC excitation signal may have a frequency range (or band), such as ranging from approximately 0.01 Hz to approximately 4 kHz. Other frequency ranges are possible for performing EIS.

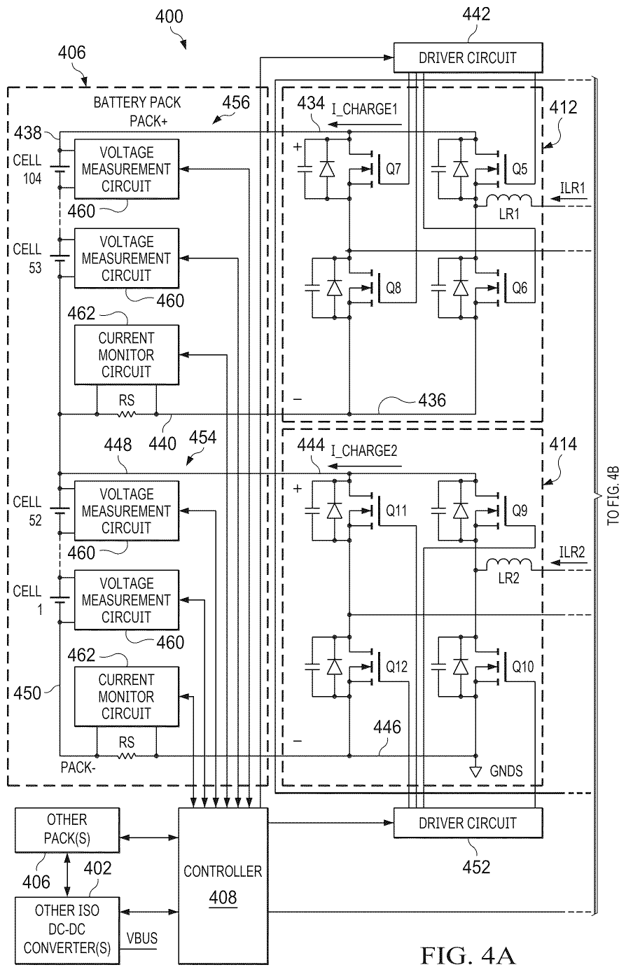

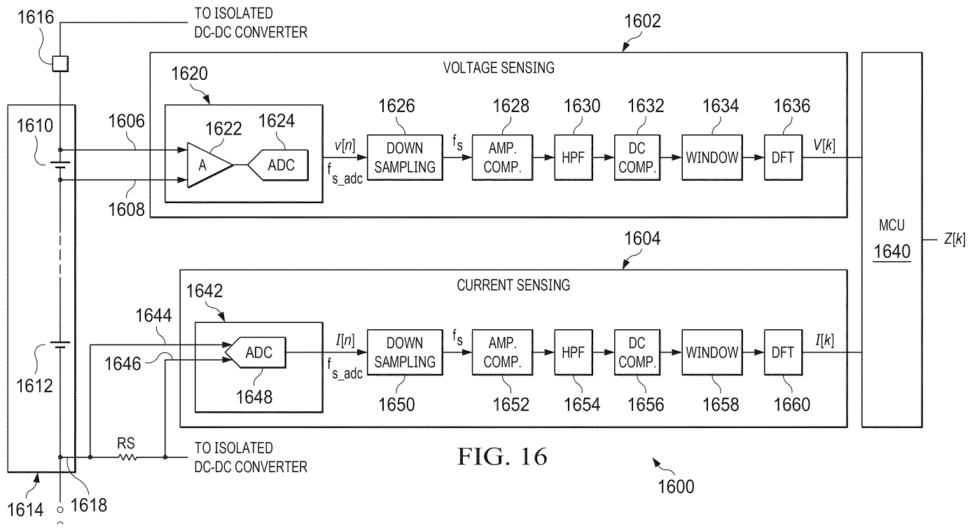

Each battery pack 110, 112, and 114 includes measurement circuitry (not shown in FIG. 1, but see, e.g., FIGS. 4 and 16) coupled to one or more battery cells of the respective pack. The measurement circuitry for a respective battery pack 110, 112, and 114 includes voltage measurement circuits (also referred to herein as cell voltage measurement circuits or voltage sensing circuits). The voltage measurement circuits measure a voltage across a respective battery cell (or cells) responsive to the AC excitation current signal. The measurement circuitry for a respective battery pack 110, 112, and 114 may also include one or more current monitor circuits to measure the current signals through the cells of the respective battery pack. The controller 122 computes the electrical impedance of a respective battery cell based on the amplitude and phase of the voltage and current measurements for the respective battery cell for multiple frequencies over the frequency range. The controller may perform EIS for each of the battery cells in the battery packs 110, 112, 114 and obtain measurements at multiple frequencies over the excitation frequency range to determine an impedance spectrum for each cell, which is the ratio between the battery cell voltage and current in the frequency domain. As an example, the controller 122 determines an indication of SOC, SOH, and/or other characteristics for one or more cells of the battery packs 110, 112, and 114 based on the impedance spectra determined for the battery cells. Advantageously, the controller 122 may control the isolated DC-DC converters 102, 104, and 106 to implement EIS and APB for the system 100, concurrently or sequentially, for different battery packs 110, 112, and 114.

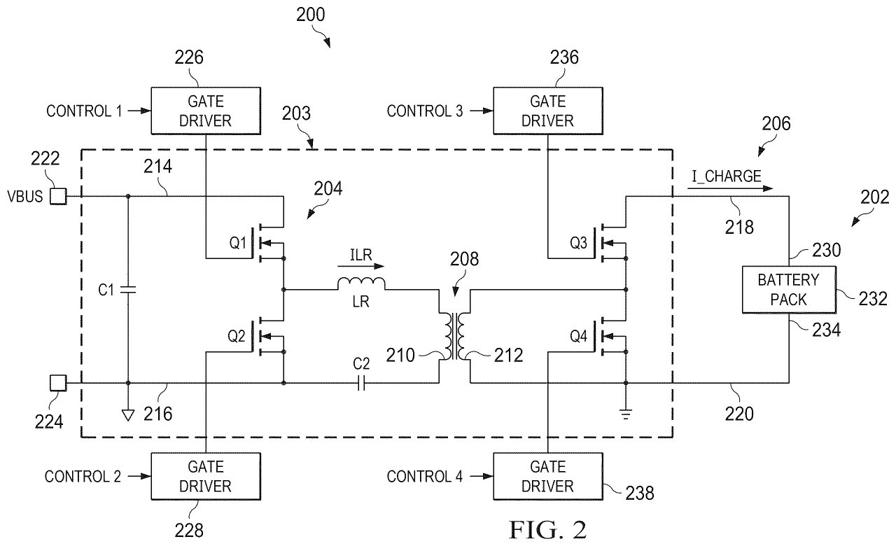

FIG. 2 illustrates an example of an ESS 200 that may be implemented for performing APB functions with respect to a battery pack 202. The ESS 200 includes a bidirectional isolated DC-DC converter 203 (referred to as an isolated DC-DC converter). The isolated DC-DC converter 203 is one example converter that may be used to implement the isolated DC-DC converters 102, 104, and 106 of the system 100 of FIG. 1. Accordingly, the description of FIG. 2 may refer to certain aspects of FIG. 1.

As shown in FIG. 2, the isolated DC-DC converter 201 includes a primary-side circuit 204, a secondary-side circuit 206, and a bidirectional isolation structure 208, in which the primary-side circuit is coupled to the secondary-side circuit through the isolation structure. In the example of FIG. 2, the isolation structure 208 is a transformer that includes a primary coil 210 (e.g., a winding) and a secondary coil 212 (e.g., a winding) that are DC isolated from each other. In other examples, the isolation structure may include more than one secondary coil. The primary-side circuit 204 includes one or more I/O terminals 214 and 216 and the secondary-side circuit 206 includes one or more I/O terminals 218 and 220. The I/O terminal 214 is coupled to one terminal 222 of a bus (e.g., a voltage bus having bus voltage VBUS) and the I/O terminal 216 is coupled to another terminal 224 of the bus coupled to a first ground, such as earth ground, signal ground, or chassis ground. A voltage potential across terminals 222 and 224 may define the bus voltage VBUS for the ESS 200. A capacitor C1 may be coupled between the bus terminals 222 and 224 to help ensure a steady DC voltage at the I/O terminals 214 and 216. The primary-side circuit 204 also includes a bridge circuit, shown as a half-bridge circuit that includes switches, shown as transistors Q1 and Q2. In other examples, depending on expected current requirements, the primary-side circuit 204 may include a full bridge circuit or be implemented according to another bridge circuit topology.

In an example, each of transistors Q1 and Q2 is a field effect transistor (FET), such as an n-channel or p-channel FET. Transistor Q1 (e.g., an n-channel FET) includes a first current terminal (e.g., drain), a second current terminal (e.g., source), and a control terminal (e.g., gate), in which the first current terminal is coupled to the I/O terminal 214, and the second current terminal is coupled to a terminal of the primary coil 210 through a resonant inductor LR. Transistor Q2 (e.g., an n-channel FET) includes a first current terminal (e.g., drain), a second current terminal (e.g., source), and a control terminal (e.g., gate), in which the first current terminal is coupled to the second current terminal (e.g., source) of Q1, and the second current terminal is coupled to the I/O terminal 216. The I/O terminal 216 of the primary-side circuit 204 is also coupled to another terminal of the primary coil 210 through a capacitor C2. LR and C2 may form a resonant tank circuit. A first gate driver 226 is coupled to the control terminal of transistor Q1 and a second gate driver 228 is coupled to the control terminal of transistor Q2.

In the secondary-side circuit 206, the I/O terminal 218 is coupled to a first terminal 230 of a battery pack 232 and the I/O terminal 220 is coupled to a second terminal 234 of the battery pack. The I/O terminal 220 is also coupled to a second ground (e.g., earth ground, signal ground, or chassis ground), which is different and isolated from the ground of the primary-side circuit 204 to which terminal 224 is coupled.

The secondary-side circuit 206 also includes a bridge circuit, shown as a half-bridge. In other examples, depending on expected current requirements, a full bridge circuit may be implemented in the secondary-side circuit 206. Additionally, or alternatively, the isolated DC-DC converter 203 may include multiple secondary-side circuits. In the example of FIG. 2, the half-bridge of the secondary-side circuit 206 includes switches, shown as transistors Q3 and Q4 (e.g., FETs). For example, transistor Q3 (e.g., a FET) includes a first current terminal (e.g., drain), a second current terminal (e.g., source), and a control terminal (e.g., gate), in which the first current terminal is coupled to the I/O terminal 218, and the second current terminal is coupled to a terminal of the secondary coil 212. Transistor Q4 (e.g., a FET) includes a first current terminal (e.g., drain), a second current terminal (e.g., source), and a control terminal (e.g., gate), in which the first current terminal is coupled to the second current terminal (e.g., source) of Q3. The second current terminal of Q4 is coupled to the I/O terminal 220, which is also coupled to another terminal of the secondary coil 212. Gate drivers 236 and 238 are coupled to the control terminals of transistors Q3 and Q4, respectively. While Q3, Q4, Q5, and Q6 are shown as FETs, in other examples, a different type of transistor may be used to implement such transistors, such as a bipolar junction transistor (BJT), insulated-gate bipolar transistor (IGBT), laterally-diffused metal-oxide semiconductor (LDMOS) transistors, or the like. One or more of the gate drivers 226, 228, 236, and 238 may be implemented in an IC chip coupled to the controller via traces on a printed circuit board or through other connections.

A controller, e.g., controller 122 of FIG. 1, provides control signals (e.g., modulated signals, such as pulse-width modulated signals or frequency-modulated signals), shown as CONTROL1, CONTROL2, CONTROL3, and CONTROL4, to inputs of each of the gate drivers 226, 228, 236, and 238. The gate drivers 226, 228, 236, and 238 may control operation Q1, Q2, Q3, and Q4 of the isolated DC-DC converter 203, such as for charging the battery pack 232 with power from the primary side or discharging the battery pack 232 to supply power to the primary side. In one example, the controller provides control signals CONTROL1, CONTROL2, CONTROL3, and CONTROL4 to control the isolated DC-DC converter 203 to charge the battery pack 232 from the primary side to, for example, support an APB or non-APB operation (e.g., normal charging/discharging of the battery packs from/to the voltage bus). In another example, the controller provides control signals CONTROL1, CONTROL2, CONTROL3, and CONTROL4 to control the isolated DC-DC converter 203 to discharge the battery pack 232 to support the APB or non-APB operation.

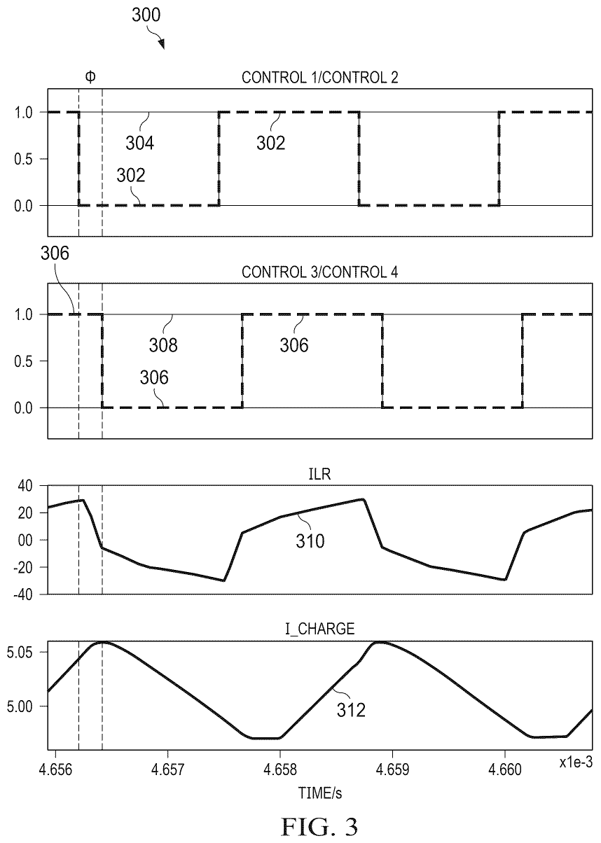

The operation of the isolated DC-DC converter 203 for charging the battery pack 232 with current I_CHARGE as part of APB will be described with respect to the signal timing diagram 300 of FIG. 3. The signal timing diagram includes plots of control signals CONTROL1, CONTROL2, CONTROL3, and CONTROL4, shown as signal pulses (e.g., square waves) 302, 304, 306, and 308, respectively. The control signals CONTROL1 and CONTROL2 are shown as complementary signal pulses 302 and 304 to provide for mutually exclusive switching operation of Q1 and Q2. Similarly, the control signals CONTROL3 and CONTROL2 are shown as complementary signal pulses 306 and 308 to provide for mutually exclusive switching operation of Q3 and Q4. Additionally, the control signals 306 and 308 (CONTROL3, and CONTROL4) are provided (e.g., by controller) with a phase transition interval, shown as (D, with respect to control signals 302 and 304 (CONTROL1 and CONTROL2).

The current ILR through the inductor LR, shown at 310 in FIG. 3, is provided through the primary coil 210 based on the control signals 302 and 304 (CONTROL1 and CONTROL2). As shown in FIG. 3, current ILR increases while control signal 302 (CONTROL1) is high and control signal 304 (CONTROL2) is low due to charging of the resonant circuit (e.g., LR, the primary coil 210, and C2) by the voltage VBUS that is provided through Q1 while Q2 is off. The current ILR decreases while control signal 304 (CONTROL2) is high and control signal 302 (CONTROL1) is low due to discharging the resonant circuit (e.g., LR, the primary coil 210, and C2) through Q2 while Q1 is off. The current ILR experiences a higher rate of change (e.g., slope) during the phase transition intervals Φ.

The time-varying current ILR 310 through the primary coil 210 induces a voltage at the secondary coil 212 (e.g., through magnetic or inductive coupling of the transformer 208), which is used to provide current I_CHARGE, shown at 312 in FIG. 3, to the battery pack 232. As shown in FIG. 3, the current I_CHARGE 312 increases in magnitude responsive to the control signal 306 (CONTROL3) being high while control signal 308 (CONTROL4) is low. The current I_CHARGE 312 decreases in magnitude responsive to the control signal 308 (CONTROL4) being high while control signal 308 (CONTROL3) is low. The voltage across the battery pack may increase based on the current I_CHARGE that is provided during APB. The current I_CHARGE 312 defines a substantially constant current, as it varies only between about 5.05 A and about 4.95 A (e.g., about 1%). In other examples, different amounts of variation (e.g., more or less than 1% variation, such as ±5%) in current I_CHARGE 312 may occur for providing substantially constant current.

To increase power efficiency, APB may involve discharging another battery pack to supply at least a portion of the energy that is used for charging the battery pack 232. APB may continue until the voltages of the respective battery packs are substantially balanced (e.g., to within a threshold voltage difference). As a further example, another instance of the isolated DC-DC converter 203 (referred to as a second isolated DC-DC converter) is coupled between the voltage bus (e.g., terminals 222 and 224) and another battery pack (referred to as a second battery pack), such as shown in FIG. 1. In this example of APB, the controller has determined that the voltage of the second battery pack is greater than the battery pack 232 that is to be charged. The controller (e.g., controller 122) controls the second isolated DC-DC converter (e.g., by providing control signals to a primary and secondary bridge circuits thereof) to generate a current in the secondary-side circuit by discharging the second battery pack. The current in the secondary-side circuit of the second isolated DC-DC converter induces a voltage on the primary coil of the primary-side circuit, which the primary-side circuit uses to provide a second voltage (e.g., a regulated DC voltage) to the terminal 222 of the voltage bus. In this way, the first and second isolated DC-DC converters performing APB cooperate to transfer energy from the second battery pack to the first battery pack. Advantageously, the second isolated DC-DC converter, which provides the voltage to the voltage bus by discharging its associated battery pack, may further reduce fluctuations in VBUS (e.g., stabilize VBUS) that are caused by the primary-side circuit 204 of the isolated DC-DC converter 203 generating current ILR for charging the battery pack 232.

FIGS. 4A and 4B illustrate another example of an ESS 400, which includes one or more bidirectional isolated DC-DC converters 402. In the example ESS 400 of FIGS. 4A and 4B, each one or more isolated DC-DC converters 402 are coupled between a bus 404 and a respective battery pack 406. The ESS 400 also includes a controller 408 coupled to each isolated DC-DC converter 402 and battery pack 406 to perform APB and/or EIS operations. The configuration of one isolated DC-DC converter 402 is shown in FIGS. 4A and 4B, and each other isolated DC-DC converter 402 in ESS 400 may be implemented as another instance thereof or as otherwise disclosed herein. The isolated DC-DC converter 402 provides an example converter that may be used to implement the converters in the system 100 of FIG. 1. Additional features of the ESS are also applicable to the ESS 200 of FIG. 2. Accordingly, the description of FIGS. 4A and 4B may refer to certain aspects of FIGS. 1, 2, and 3.

As an example, the isolated DC-DC converter 402 includes a primary-side circuit 410 and one or more secondary-side circuits, shown in FIGS. 4A and 4B as a first secondary-side circuit 412 and a second secondary-side circuit 414. The primary-side circuit 410 is coupled to each of the secondary-side circuits 412 and 414 via a bidirectional isolation structure 416. For example, the bidirectional isolation structure 416 is implemented as a transformer that includes a primary coil 418 and one or more secondary coils 420 and 422, where the primary coil is DC-isolated from each of the one or more secondary coils. Each of the primary coil 418 and secondary coils has a number of windings (or turns) shown as N1, N2, and N3, respectively, and a voltage ratio between the coils is proportional to the ratio of the number of turns of the respective coils. The primary-side circuit 410 is coupled to the primary coil 418. The secondary-side circuit 412 is coupled to the secondary coil 420 and the secondary-side circuit 414 is coupled to the secondary coil 422.

As shown in FIG. 4B, the primary-side circuit 410 includes one or more I/O terminals 424 and 426, which are coupled to one or more respective terminals 428 and 430 of the bus 404. For example, the terminal 424 has a first voltage (e.g., a positive voltage, such as about 24 V) and the terminal 426 has a second, lower voltage, such as ground (e.g., earth ground or chassis ground), and the voltage across terminals 424 and 426 defines a bus voltage VBUS for the ESS 400.

In the example of FIG. 4B, the primary-side circuit 410 includes a full bridge circuit, having an arrangement of switches, shown as transistors Q1, Q2, Q3, and Q4, such as FETs. Other types of transistors may be used, as disclosed herein. Q1 and Q2 may define a first half of the bridge circuit and Q3 and Q4 define another half of the bridge circuit. For example, transistor Q1 (e.g., a FET) includes a first current terminal (e.g., drain), a second current terminal (e.g., source), and a control terminal (e.g., gate), in which the first current terminal is coupled to the I/O terminal 424, and the second current terminal is coupled to a terminal of the primary coil 418. Transistor Q2 (e.g., a FET) includes a first current terminal (e.g., drain), a second current terminal (e.g., source), and a control terminal (e.g., gate), in which the first current terminal is coupled to the second current terminal (e.g., source) of Q1, and the second current terminal is coupled to the I/O terminal 426. Additionally, transistor Q3 (e.g., a FET) includes a first current terminal (e.g., drain), a second current terminal (e.g., source), and a control terminal (e.g., gate), in which the first current terminal is coupled to the I/O terminal 424, and the second current terminal is coupled to another terminal of the primary coil 418 through one or more switches, shown as one or more transistor Q13 (e.g., one or more FETs). Transistor Q4 (e.g., a FET) includes a first current terminal (e.g., drain), a second current terminal (e.g., source), and a control terminal (e.g., gate), in which the first current terminal is coupled to the second current terminal (e.g., source) of Q3, and the second current terminal is coupled to the I/O terminal 426.

A driver circuit 432 has one or more inputs and outputs, in which the one or more inputs are coupled to one or more outputs of the controller 408 and the outputs of the driver circuit are coupled to respective control inputs of Q1, Q2, Q3, Q4, and Q13. The driver circuit 432 controls transistors Q1, Q2, Q3, Q4, and Q13 based on one or more control signals received from the controller 408 to control flow of energy to or from the bus 404, such as described herein. In one example, the controller 408 controls the primary-side circuit 410 to transfer energy from the bus 404 and through the bidirectional isolation structure 416 to one or both of the secondary-side circuits 412 and 414. In another example, the controller 408 controls the primary-side circuit 410 to transfer energy from one or both of the secondary-side circuits 412 and 414, which is received via the primary coil 418 through the bidirectional isolation structure 416, to the bus 404.

As shown in FIG. 4A, the secondary-side circuit 412 includes an arrangement of switches, shown as transistors Q5, Q6, Q7, and Q8 (e.g., FETs) configured as a full-bridge circuit, in which Q5 and Q6 may define a first half bridge and Q7 and Q8 define another half bridge. For example, transistor Q5 (e.g., a FET) includes a first current terminal (e.g., drain), a second current terminal (e.g., source), and a control terminal (e.g., gate), in which the first current terminal is coupled to an I/O terminal 434 of the secondary-side circuit 412, and the second current terminal is coupled to a first terminal of the secondary coil 420 through an inductor LR1. Transistor Q6 (e.g., a FET) includes a first current terminal (e.g., drain), a second current terminal (e.g., source), and a control terminal (e.g., gate), in which the first current terminal is coupled to the second current terminal (e.g., source) of Q5, and the second current terminal is coupled to another I/O terminal 436 of the secondary-side circuit. Further, transistor Q7 (e.g., a FET) includes a first current terminal (e.g., drain), a second current terminal (e.g., source), and a control terminal (e.g., gate), in which the first current terminal is coupled to the I/O terminal 434, and the second current terminal is coupled to a second terminal of the secondary coil 420. Transistor Q8 (e.g., a FET) includes a first current terminal (e.g., drain), a second current terminal (e.g., source), and a control terminal (e.g., gate), in which the first current terminal is coupled to the second current terminal (e.g., source) of Q7, and the second current terminal is coupled to the I/O terminal 436. The I/O terminals 434 and 436 of the secondary-side circuit 412 are coupled to battery terminals 438 and 440, respectively, of the battery pack 406. A driver circuit 442 has one or more inputs and outputs, in which the one or more inputs are coupled to one or more outputs of the controller 408 and the outputs of the driver circuit are coupled to respective control inputs of transistors Q5, Q6, Q7, and Q8. The driver circuit 442 controls transistors Q5, Q6, Q7, and Q8 based on one or more control signals received from the controller 408 to control flow of energy, shown as current I_CHARGE1, to or from the battery terminal 438, such as described herein.

The other secondary-side circuit 414 includes an arrangement of switches, shown as transistors Q9, Q10, Q11, and Q12 (e.g., FETs) configured as a full-bridge circuit, in which Q9 and Q10 may define a first half bridge and Q11 and Q12 define another half bridge. For example, transistor Q9 (e.g., a FET) includes a first current terminal (e.g., drain), a second current terminal (e.g., source), and a control terminal (e.g., gate), in which the first current terminal is coupled to an I/O terminal 444 of the secondary-side circuit 414, and the second current terminal is coupled to a first terminal of the secondary coil 422 through an inductor LR2. Transistor Q10 (e.g., a FET) includes a first current terminal (e.g., drain), a second current terminal (e.g., source), and a control terminal (e.g., gate), in which the first current terminal is coupled to the second current terminal (e.g., source) of Q9, and the second current terminal is coupled to another I/O terminal 446 of the secondary-side circuit 414, which is also coupled to a ground (e.g., earth or chassis ground). The ground coupled to the I/O terminal 446 is different and electrically isolated from the ground on the primary side that is coupled to terminal 430. Further, transistor Q11 (e.g., a FET) includes a first current terminal (e.g., drain), a second current terminal (e.g., source), and a control terminal (e.g., gate), in which the first current terminal is coupled to the I/O terminal 444, and the second current terminal is coupled to another terminal of the secondary coil 422. Transistor Q12 (e.g., a FET) includes a first current terminal (e.g., drain), a second current terminal (e.g., source), and a control terminal (e.g., gate), in which the first current terminal is coupled to the second current terminal (e.g., source) of Q11, and the second current terminal is coupled to the I/O terminal 446. The I/O terminals 444 and 446 of the secondary-side circuit 414 are coupled to battery terminals 448 and 450, respectively, of the battery pack 406. A driver circuit 452 has one or more inputs and outputs, in which the one or more inputs are coupled to one or more outputs of the controller 408 and the outputs of the driver circuit are coupled to respective control inputs of transistors Q9, Q10, Q11, and Q12. The driver circuit 452 controls transistors Q9, Q10, Q11, and Q12 based on one or more control signals received from the controller 408 to control flow of energy, shown as current I_CHARGE2, to or from the battery terminal 448, such as described herein.

Additionally, the battery pack 406 includes a plurality of battery cells (e.g., coupled in series, in parallel, or a combination of both) between battery terminals 438 and 450. In the example of FIGS. 4A and 4B, there are 104 battery cells, numbered as CELL 1 through CELL 104. The battery pack 406 may include other numbers of battery cells in other examples. Further, in the example of FIG. 4A, battery CELL 1 through battery CELL 52, which are coupled between battery terminals 438 and 440, can be part of one module 454 of the battery pack 406 and battery CELL 53 through battery CELL 104, which are coupled between battery terminals 448 and 450, can be part of another module 456 of the battery pack. In other examples, more than two modules may be included in a battery pack 406 or the battery pack may define a single module (or not include any modules). As described herein, the controller 408 controls one or more of the isolated DC-DC converters 402 in the ESS 400 to perform an APB operation. The controller 408 can also control the isolated DC-DC converters 402 to perform non-APB operations, such as charging/discharging of the battery packs from/to the voltage bus.

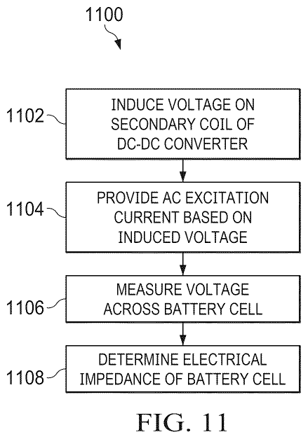

In some examples, the battery pack 406 includes one or more voltage measurement circuits 460, such as one or more analog or digital volt meters. For example, each voltage measurement circuit 460 includes inputs coupled across a respective battery cell (e.g., CELL 1 through CELL 104) and an output coupled to the controller 408. Each voltage measurement circuit 460 measures the cell voltage of a respective battery cell (or multiple cells) and provides an indication of the measured voltage to the controller 408. For example, the indication of the measured cell voltages represent respective battery cell voltages that are responsive to an AC excitation current signal provided by one or more of the secondary-side circuits 412 or 414 to a respective module 456 or 454 for performing EIS such as described herein (see, e.g., FIGS. 11-15). Additionally, or alternatively, another voltage measurement circuit 460 may be coupled across the battery cells of a respective module 454 or 456, such as one voltage measurement circuit having inputs coupled to battery terminals 438 and 440 and another voltage measurement circuit having inputs coupled to battery terminals 448 and 450. In another example, a respective voltage measurement circuit 460 has inputs coupled to battery terminals 438 and 450 to enable sensing a pack voltage (e.g., between PACK+ and PACK−).

The battery pack 406 also includes one or more current monitor circuits 462. For example, each current monitor circuit 462 has inputs coupled across a sense resistor RS that is connected in series with the current path of through the battery cells between battery terminals 438 and 450 (e.g., the current path of the excitation signal for each module 454 and 456). Each current monitor circuit 462 has an output coupled to a respective input of the controller 408 for providing a current sense signal representative of the sensed current. As described herein, the controller 408 controls one or more of the isolated DC-DC converters 402 in the ESS 400 to perform APB, EIS, or a combination of APB and EIS (e.g., by controlling charging or discharging of current with respect to the cells of the battery pack).

In some examples, another voltage measurement circuit (not shown in FIGS. 4A and 4B) may be coupled to bus 404 to measure the voltage VBUS, which can be provided to controller 408 via, for example, a feedback data channel (e.g., an optical link, capacitors, transformers, etc.). Alternatively, the voltage measurement circuit may be part of the controller 408.

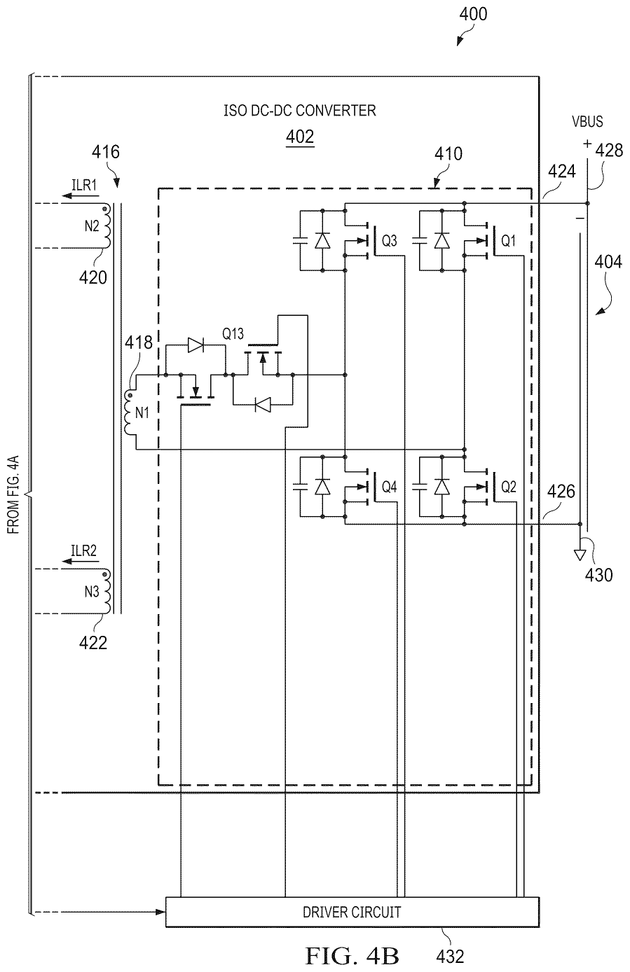

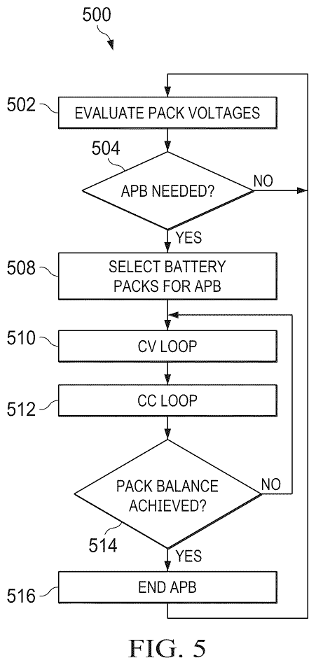

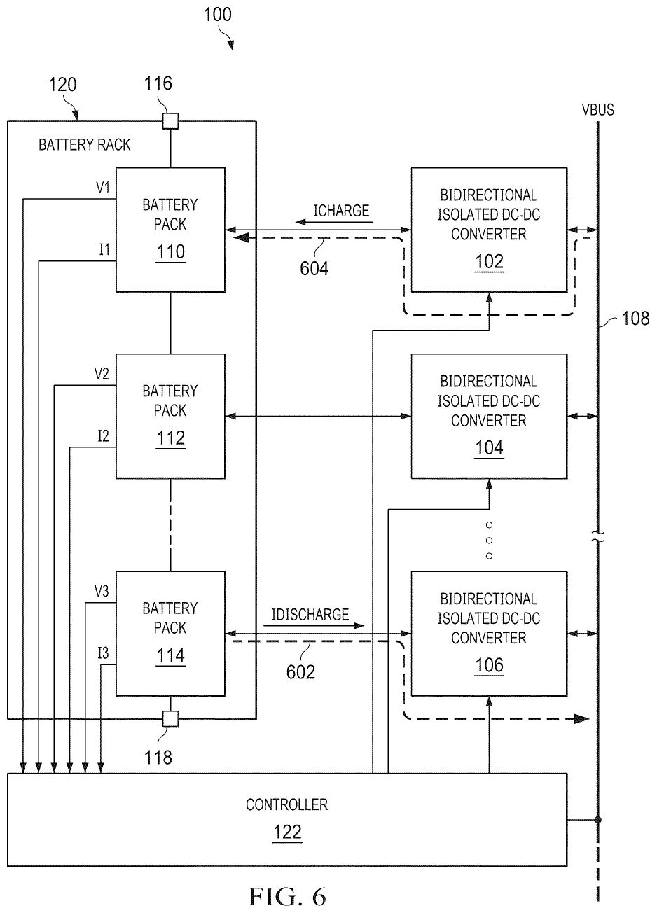

FIG. 5 is a flow diagram showing an example method 500 of performing APB. The method 500 may be implemented by the systems of FIGS. 1, 2, and 4. For example, machine-readable instructions may be stored in memory of the controller (e.g., controller 122, 408) that, when executed by one or more processors of the controller, cause the one or more processors to perform the method 500. Accordingly, the description of FIG. 5 may refer to certain aspects of FIGS. 1, 2, 3, and 4. The method 500 is further described with respect to FIGS. 6 and 7.

The method 500 begins at 502 in which one or more battery pack voltages are evaluated. For example, the evaluation at 502 is made (e.g., by controller 122, 408) based on a voltage measured across terminals of one or more battery packs (e.g., across terminals 230 and 234 or across battery terminals 438 and 450 based on, e.g., outputs of voltage measurement circuits 460). At 504 a determination is made whether APB is needed based on the evaluation at 504. For example, the controller 122, 408 analyzes the voltages of various battery packs to determine if the voltage difference between two or more packs exceeds a specified threshold, and/or if one or more packs deviate from a target voltage by at least the same or different specified threshold. In response to a negative determination at 504 (“NO”), indicating that differences in battery pack voltages among the battery packs is below the voltage threshold, the method returns to 502 to continue monitoring and evaluating voltages of the respective battery packs (e.g., according to a measurement interval). In response to a positive determination at 504 (“YES”), indicating differences in battery pack voltages among the battery packs exceeds the voltage threshold, the method proceeds to 508 (e.g., entering an APB operating mode) to select one or more pairs of battery packs for performing APB. As an example, a pair of battery packs may be selected (at 508) to include the battery pack having the highest pack voltage and the battery pack having the lowest pack voltage. In other examples, more than two battery packs may be selected at 508, such that APB may be performed concurrently with respect to more than two battery packs (e.g., 3 battery packs, 4 battery packs, 5 battery packs, or more). For sake of simplicity of explanation, the remaining description of FIG. 5 describes the APB method 500 for two battery packs selected at 508.

At 510, an isolated DC-DC converter coupled to the battery pack selected (at 508) as having the highest pack voltage, is controlled in a constant voltage (CV) loop to provide voltage to the voltage bus by discharging the highest-voltage battery pack. For example, the controller 408 can implement the constant voltage loop by changing the pulse-width or frequency of the transistors of the primary-side circuit based on sensed bus voltage and/or current feedback. Additionally, at 512 another isolated DC-DC converter coupled to the battery pack selected (at 508) as having the lowest pack voltage, is controlled in a constant current (CC) loop to provide current to charge the lowest-voltage battery pack based on the voltage of the voltage bus. The controller 408 can implement the constant current loop by changing the pulse-width or frequency of the transistors on one or more secondary-side circuits based on sensed battery pack current and/or sensed voltage feedback. As a further example, the constant voltage loop and constant current loop, which are used for transferring charge between the respective battery packs may be implemented by a proportional-integral (PI) control function implemented by the controller (e.g., controller 122 or 408) of the ESS while sensing, respectively, the voltage bus and the current to the battery pack with the lowest pack voltage (e.g., via current monitor circuit 462). The controller may implement the constant voltage loop and constant current loop according to other types of control methods (e.g., proportional-integral-derivative (PID) control or machine learning methods, such as fuzzy logic control and neural network control) in other examples.

At 514, the method includes determining whether pack balance has been achieved for the battery packs selected at 510 and 512. In response to a positive determination at 514 (“YES”), indicating that the selected battery packs are substantially balanced (e.g., to within a threshold voltage difference, such as a percentage or voltage value), the method proceeds to 516 and APB ends. From 516, the method 500 may return to 502 to continue evaluating battery pack voltages to control whether APB will be performed on battery packs. In response to a negative determination at 514 (“NO”), indicating that balance has not yet been achieved, the method returns to 510 to continue balancing by actively charging and discharging the selected battery packs. The method 500 may loop between 508 and 514 until pack balance has been achieved.

As a further example, FIG. 6 is a block diagram demonstrating the APB method 500 of FIG. 5 implemented in the context of the ESS 100 of FIG. 1. As shown in FIG. 6, each of the battery packs 110, 112, and 114 have respective battery pack voltages shown as V1, V2, and V3. The controller 1200 receives signals representative of the battery pack voltages V1, V2, and V3 measured by voltage measurement circuits (e.g., voltage measurement circuits 460). The controller 122 also receives signals I1, I2, and I3 representative of current through the battery packs 110, 112, and 114, respectively, as measured by current monitor circuits (e.g., current monitor circuits 460). For example, prior to performing APB and assuming a target pack voltage of approximately 48 V, V1=40 V, V2=48 V, and V3=58 V. As a result, the controller 122 selects (at 508) battery pack 114 as having the highest voltage V3 and battery pack 110 as having the lowest voltage V1. The controller 122 controls the isolated DC-DC converter 106 (e.g., in a constant voltage loop) to sink current (labelled IDISCHARGE) from battery pack 114 and provide a regulated (e.g., substantially constant) voltage to the voltage bus 108, as shown by dashed line 602. The controller 122 can control the isolated DC-DC converter 106 in a constant voltage loop based on, for example, adjusting the pulse width (e.g., in a PWM scheme) or frequency (in a frequency modulation scheme). Additionally, the controller 122 controls the isolated DC-DC converter 102 (e.g., in a constant current loop, through controlling the phase angle between primary-side and secondary-side switches) to source (e.g., substantially constant) current (labelled ICHARGE) to battery pack 110 based on voltage VBUS of the bus 108, as shown by dashed line 604. The controller 122 controls the isolated DC-DC converters 102 and 106 to provide the charge and discharge currents based on current signals I1 and I3 measured (e.g., by current monitor circuit 462) for the respective battery packs. The voltage provided to the bus by the isolated DC-DC converter 106 mitigates fluctuations to facilitate operating the isolated DC-DC converter 102 in a constant current mode.

Specifically, during the charging, the voltage VBUS may rise, and during the discharging, the voltage VBUS may fall. By regulating the voltage VBUS at a constant value (e.g., through the CV loop), the effect of fluctuations of the voltage VBUS on the charging/discharging of the battery packs can be mitigated. Also, by regulating the voltage VBUS and the charging current, it can also be ensured that the discharge module power (the power obtained from discharging from the high voltage battery pack) equals or exceeds the charge module power (the power delivered to the low voltage battery pack via charging). All these can facilitate the APB operation. The controller 122 continues to control the isolated DC-DC converters 102 and 106 until it has been determined (at 514) that pack balance has been achieved.

As a further example, referring back to FIGS. 4A and 4B, the controller 408 controls isolated DC-DC converters 402 of the ESS 400 to perform APB by transferring charge to or from the battery pack 406, such as to transfer energy from one battery pack to another battery pack of the ESS. In a first example where APB is being implemented to transfer energy from the bus to the battery pack 406, the controller 408 controls the bridge circuit (e.g., Q1, Q2, Q3, and Q4) and switch Q13 of primary-side circuit 410 to provide an AC current to primary coil 418 based on bus voltage VBUS. The AC current through the primary coil 418 induces a voltage at the secondary coils 420 and 422 (e.g., through magnetic or inductive coupling). Based on the voltage induced at secondary coil 420, the controller 408 further controls the bridge circuit (e.g., Q5, Q6, Q7, and Q8) of the secondary-side circuit 412 to provide current I_CHARGE1 (e.g., substantially constant current) to the battery terminal 438 for charging the battery pack 406. Additionally, or alternatively, based on the voltage induced at the secondary coil 422, the controller 408 controls the bridge circuit (e.g., Q9, Q10, Q11, and Q12) of the secondary-side circuit 414 to provide current I_CHARGE2 (e.g., substantially constant current) to the battery terminal 448.

In a second example where APB is being implemented to transfer from the battery pack 406 to the bus 404, the controller 408 controls the bridge circuit (e.g., Q5, Q6, Q7, and Q8) of the secondary-side circuit 412 to provide AC current (ILR1) through LR1 and the secondary coil 420 by discharging current I_CHARGE1 from the terminal 438 of the battery pack 406. As the energy in the battery pack 406 is discharged by providing current to the secondary coil 420, the voltage of the battery pack decreases accordingly. Additionally, or alternatively, the controller 408 controls the bridge circuit (e.g., Q9, Q10, Q11, and Q12) of the secondary-side circuit 414 to provide AC current (ILR2) through LR2 and the secondary coil 420 by discharging current I_CHARGE2 from the terminal 448 of the battery pack 406. Continuing with the second example, the controller 408 controls the bridge circuit (e.g., Q1, Q2, Q3, and Q4) and switch Q13 of primary-side circuit 410 to provide a substantially constant (e.g., regulated) voltage to the bus 404 (e.g., across bus terminals 428 and 430) based on the voltage induced at the primary coil 418 through the isolation structure 416 by current through the secondary coil(s) 420 and/or 422. The controller 408 controls the primary-side circuit 410 based on closed loop feedback (e.g., a measure of VBUS) so the bus voltage VBUS remains substantially constant during APB.

As another example, FIG. 7 is a schematic diagram illustrating APB for an ESS 700 that includes bidirectional isolated DC-DC converters 702a and 702b coupled between a bus 703 (e.g., a voltage bus having bus voltage VBUS) and respective battery packs 704a and 704b. In FIG. 7, each of the isolated DC-DC converters 702a and 702b have the same configuration. Other converter configurations are possible. The isolated DC-DC converter 702a includes a primary-side circuit 706a and multiple secondary-side circuits 708a and 710a, which are magnetically coupled to each other through respective coils of a transformer 712a. Each secondary-side circuit 708a and 710a may include an inductor L2a and L3a, respectively. The isolated DC-DC converter 702b also includes a primary-side circuit 706b and multiple secondary-side circuits 708b and 710b, which are magnetically coupled to each other through respective coils of a transformer 712b. The isolated DC-DC converters 702a and 702b may be implemented according to any of the examples disclosed herein. For example, each of the primary-side circuits 706a and 706b and secondary-side circuits 708a, 710a, 708b, and 710b may include a bridge circuit (e.g., a half-bridge or full-bridge), which may be configured according to expected current requirements of the respective circuits.

As shown in FIG. 7, the isolated DC-DC converters 702a and 702b are transferring energy from one battery pack 704b to the other battery pack 704a for performing APB between respective battery packs. For example, an arrow 714 shows energy flow from the bus to battery pack 704a responsive to controlling primary-side circuit 706a and secondary-side circuits 708a and 710a for charging the battery pack 704a (e.g., with substantially constant current), as disclosed herein. Additionally, another arrow 716 shows energy flow from battery pack 704b to the bus 703 responsive to controlling primary-side circuit 706b and secondary-side circuits 708b and 710b for discharging the battery pack 704b and providing voltage to the bus 703, as disclosed herein. Advantageously, fluctuations on the bus 703 caused by the energy transfer 714 from the bus to the battery pack 704a as well as other voltage and current demands on the bus may be mitigated based on the energy transfer 716 from the battery pack 704b to the bus.

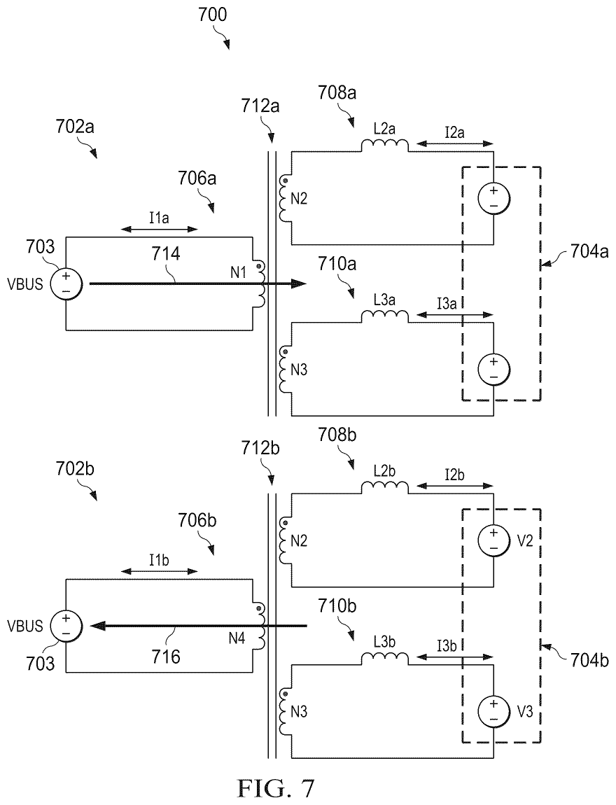

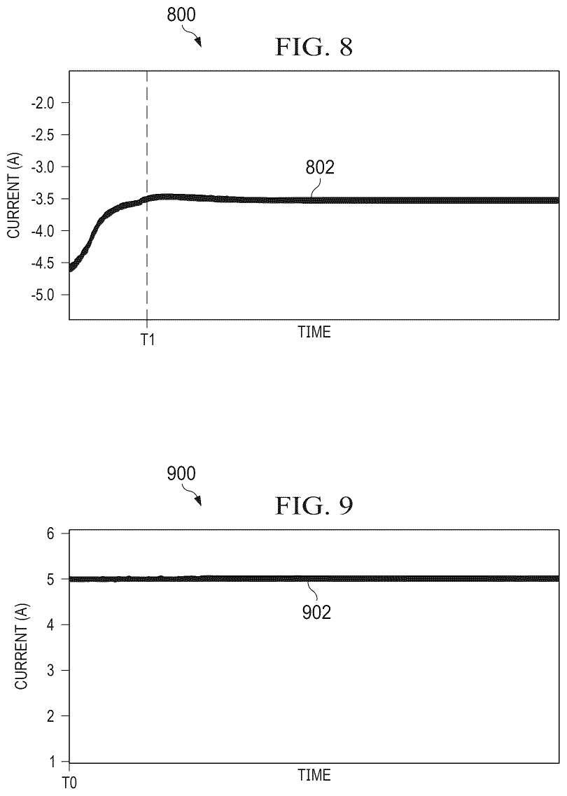

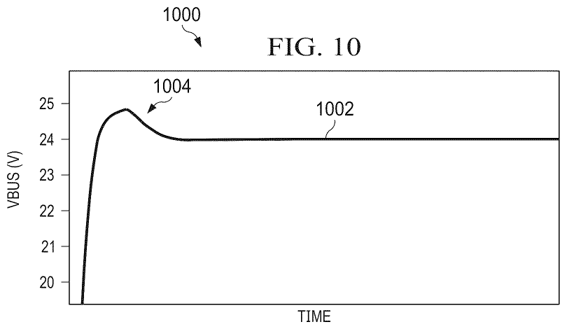

FIGS. 8, 9, and 10 are graphs demonstrating examples of waveforms for an ESS performing APB. For ease of explanation, FIGS. 8, 9, and 10 are described with respect to the ESS 100 shown in FIG. 6. The APB concepts described with respect to FIG. 6 are applicable to other example embodiments disclosed herein. For example, FIG. 8 is a plot 800 showing an example of discharge current 802 (IDISCHARGE) from the higher-voltage battery pack 114 based on operating isolated DC-DC converter 106 in a constant voltage (CV) loop to transfer energy to its primary-side circuit and provide an output voltage to stabilize the VBUS, such as described herein. In the CV loop, the controller 122 controls the discharge current based on the pack voltage. As shown in FIG. 8, the discharge current 802 from the battery pack increases in magnitude until a time T1 where it approximates 3.5 A based on the CV loop of isolated DC-DC converter 106. FIG. 9 is a plot 900 showing an example of charge current (labelled ICHARGE) provided to the lower-voltage battery pack 110 based on operating isolated DC-DC converter 102 in a constant current (CC) loop to transfer energy to its secondary-side circuit and provide ICHARGE. As shown in FIG. 9, isolated DC-DC converter 102 provides the current ICHARGE at about 5 A, beginning at time TO, for charging the battery pack 110. Also, a comparison between FIGS. 8 and 9 demonstrates that the discharge current 802 may be lower than the charge current 902 during APB. FIG. 10 is a plot 1000 showing voltage 1002 of the bus 108 during APB, which is demonstrated as being stable during APB. The bus voltage 1002 initially shoots above the target voltage, shown at 1004, and then stabilizes to the target voltage of approximately 24 V based on operation of isolated DC-DC converter 106. Advantageously, based on operating the isolated DC-DC converter 106 in the CV loop, the DC bus voltage of approximately 24 V may be resistant to fluctuations, including responsive to current drawn by the isolated DC-DC converter 102.

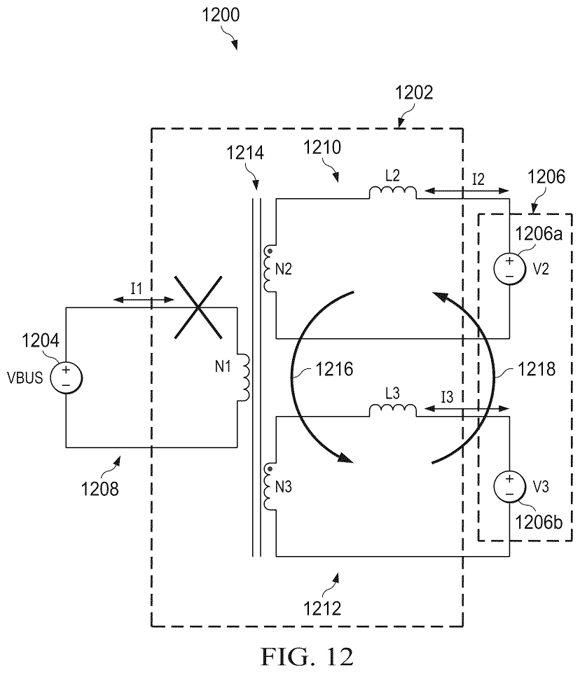

FIG. 11 is a flow diagram showing an example method 1100 of performing EIS. The method 1100 may be implemented by the systems of FIGS. 1, 2, and 4. For example, machine-readable instructions may be stored in memory of the controller (e.g., controller 122, 408) that, when executed by one or more processors of the controller, cause the one or more processors to perform the method 1100. The controller (e.g., controller 122, 408) can execute the EIS method 1100 in combination with the APB method 500 of FIG. 5, sequentially or in parallel (e.g., concurrently). Accordingly, the description of FIG. 11 may refer to certain aspects of FIGS. 1, 2, 4A, and 4B. The method 1100 is further described with respect to FIGS. 12, 13, and 14.

At 1102, the method 1100 includes inducing a voltage at a secondary coil of a DC-DC converter. For example, as shown in FIGS. 4A and 4B, the isolated DC-DC converter 402 includes primary-side circuit 410 coupled to two secondary-side circuits through a bidirectional isolation structure 416 implemented as a transformer, which includes a primary coil 418 and one or more secondary coils 420 and 422. The primary coil 418 and secondary coils 420 and 422 are magnetically coupled to each other. As an example, the voltage may be induced at the secondary coil 420 based on voltage and current at the primary coil 418 or at the other secondary coil 422. Similarly, a voltage may be induced at the secondary coil 422 based on voltage and current at the primary coil 418 and/or at the secondary coil 420. In examples where the voltage is induced at one secondary coil 420 or 422 based on a changing current provided at the other secondary coil 422 or 420, the primary-side circuit 410 may operate in an open circuit condition (e.g., by turning off transistor Q13) so no energy transfers through the transformer to the primary-side circuit. The voltage induced at the secondary coil 420 or 422 further may depend on the relative turns ratio of the respective coils.

At 1104, an AC excitation current is provided based on the induced voltage. For example, as shown in FIGS. 4A and 4B, secondary-side circuit 412 provides an AC excitation current signal at I/O terminal 434 of the secondary-side circuit based on the voltage induced at the secondary coil 420. Alternatively, secondary-side circuit 414 provides an AC excitation current signal at I/O terminal 444 of the secondary-side circuit based on the voltage induced at the secondary coil 422. As mentioned above, the voltage may be induced at the secondary coil 420 or 422 based on current through the primary coil 418 (e.g., as shown in FIG. 6 as part of APB operation) or the other secondary coil.

As a further example, still referring to FIGS. 4A and 4B and the method 1100 of FIG. 11, the controller 408 controls secondary-side circuits 412 and 414 for performing EIS based on transfer of energy within the battery pack 406 while turning off (e.g., disabling) the primary-side circuit 410 so as not to involve energy transfer with respect to the bus 404. For example, controller 408 controls the bridge circuit (e.g., Q5, Q6, Q7, and Q8) of secondary-side circuit 412 to provide AC current I_CHARGE1 to the I/O terminal 434, such as for performing EIS on one or more cells of the module 456 (e.g., one or more of CELL 53 through CELL 104), based on the voltage induced at the secondary coil 420 through the bidirectional isolation structure 416 (e.g., induced by the secondary-side circuit 414). Additionally, the controller 408 controls the bridge circuit (e.g., Q9, Q10, Q11, and Q12) of the secondary-side circuit 414 to provide current I_CHARGE2, based on the voltage at battery terminal 448, which is received at I/O terminal 444 to induce the voltage at the secondary coil 420. The controller 408 further turns off Q13 to deactivate the primary-side circuit 410 by preventing current flow through the primary coil 418. Alternatively, the controller 408 may control the secondary-side circuit 414 to provide the AC excitation current signal I_CHARGE2 to the I/O terminal 444, such as for performing EIS on one or more cells of the module 454 (e.g., one or more of CELL 1 through CELL 52), based on the voltage induced at the secondary coil 422 through the isolation structure 416 (e.g., induced by the secondary-side circuit 412). The controller 408 may control one or more parameters of the AC excitation current signals I_CHARGE1 and/or I_CHARGE2 when performing EIS, including, for example, amplitude, phase, frequency range, frequency resolution, the number of frequencies (e.g., bins or tones) simultaneously run, PWM modulation frequency of the FETs, etc.

At 1106, the method 1100 includes measuring a voltage across one or more battery cells. For example, as shown in FIG. 4, the voltage measurement circuits 460 measure the voltage across each respective cell based on the AC excitation current signal provided to the battery terminal 438 or 448, which is coupled to the output of the secondary-side circuit 412 or 414 that provide the AC excitation current signal. In a first example, when controller 408 controls secondary-side circuit 412 to provide the AC excitation current signal to battery terminal 438 of battery pack 406, controller 408 receives (and stores) voltage measurements from voltage measurement circuits 460 of the module 456. In a second example, when controller 408 controls secondary-side circuit 414 to provide the AC excitation current signal to battery terminal 448 of battery pack 406, controller 408 receives (and stores) voltage measurements from voltage measurement circuits 460 of the module 454. The voltage measurements may include magnitude and phase of the cell voltages over a range of frequencies of the AC excitation current signal that is provided.

As a further example, the AC excitation current signal also may be measured (e.g., by current monitor circuit 462) in combination with the voltage measurements at 1106. As described above, the secondary-side circuit 412 or 414 may provide the AC excitation current signal with a frequency that varies over a range of frequencies (e.g., about 0.01 Hz to about 4 kHz). Controller 408 thus may acquire a measure of the AC excitation current signal, including current magnitude and frequency, for each voltage measurement, which measurements are stored in memory of the controller for further processing. The controller 408 may control a sample rate or other parameters for each of the voltage and current measurements (e.g., by voltage measurement circuits 460 and current monitor circuit 462). Additionally, the voltage measurement circuits 460 and current monitor circuits 462 may be synchronized to a reference (e.g., system) clock signal so that measurements for EIS are synchronized to within an acceptable error threshold, Additionally, the controller may include a timestamp with each of the voltage and current measurements that are stored in memory.

At 1108, the method 1100 includes determining an electrical impedance of one or more battery cells based on the measured voltage for the respective cell(s) and the AC excitation current signal. For example, the controller 408 computes electrical impedance and/or impedance spectra for one or more (e.g., each) of the battery cells (e.g., CELL 1 through CELL 104) based on the voltage and AC excitation current signal measured for each respective battery cell (e.g., measurements by cell voltage measurement circuits 460 and current monitor circuit 462). The controller 408 computes electrical impedance or impedance spectra as including values representative of real impedance component (e.g., resistance), an imaginary impedance component (e.g., reactance), or both of real and imaginary components (e.g., according to Ohm's law, complex impedance may be determined as

$$Z ( ω ) = \frac{V ( ω )}{I ( ω )} ,$$

where ω represents the angular frequency in the frequency domain). The controller 408 determines impedance and/or impedance spectra (at 1108) for one or more cells of the battery pack 406 based on the voltage and current measurements at multiple frequencies over the frequency range of the AC excitation current signal, which may depend on the frequency resolution of the excitation current signal and the sample rate for the measurements.

It is known that one or more components (e.g., real and/or imaginary components) of the impedance or impedance spectra for different ranges of frequencies may provide indicators for different conditions or parameters of the battery cells and/or battery pack. For example, the controller 408 may identify frequencies that impedance varies based on the desired cell characteristic or create an equivalent circuit model. The controller 408 calculates estimates of one or parameters or conditions for the battery cells and/or the battery pack 406, more generally, such as including SOC and/or SOH indicators, based on the impedance or impedance spectra. Additionally, or alternatively, the controller may predict thermal runaway for the battery pack based the impedance over a range of frequencies. While the calculations and analysis based on the measurements during EIS have been described as being performed by the controller, in addition, or as an alternative, some or all such calculations and analyses may be performed by another computing device external to the controller.

As a further example FIG. 12 is a schematic diagram illustrating EIS being performed for an ESS 1200. The ESS 1200 includes one or more (one shown in FIG. 12) bidirectional isolated DC-DC converters 1202 coupled between a bus 1204 (e.g., a voltage bus having bus voltage VBUS) and a battery pack 1206. The battery pack 1206 includes a plurality of battery cells arranged in series between battery terminals, which may be arranged to define respective battery modules 1206a and 1206b. Each battery module 1206a and 1206b includes a respective portion (e.g., half) of the total number of cells. As shown in FIG. 12, I/O terminals of the secondary-side circuit 1210 are coupled across the battery module 1206a and the I/O terminals of the secondary-side circuit 1212 are coupled across the battery module 1206b.

The DC-DC converter 1202 may be implemented according to any topology, such as disclosed herein. As shown in FIG. 12, the DC-DC converter 1202 includes a primary-side circuit 1208 and multiple secondary-side circuits 1210 and 1212, which are magnetically coupled to each other through respective coils of a transformer 1214. Each secondary-side circuit 1210 and 1212 may include an inductor L2 and L3, respectively. The DC-DC converters 1202a and 1202b may be implemented according to any of the examples disclosed herein. For example, each of the primary and secondary-side circuits 1208, 1210, and 1212 may include a bridge circuit (e.g., a half-bridge or full-bridge), which may be configured according to expected current requirements of the respective circuits. Current through the primary-side circuit is shown as I1 and current through each of the secondary-side circuits 1210 and 1212 is shown as I2 and I3, respectively.

The DC-DC converter 1202 is configured to provide AC excitation current signals for performing EIS, such as described herein. In the example of FIG. 12, the AC excitation current signals I2 and 13 are provided to respective battery cells of battery modules 1206a and 1206b based on the energy in the respective battery modules 1206a and 1206b and energy that is being transferred directly between the secondary-side circuits 1210 and 1212, as shown by arrows 1216 and 1218, while the primary-side circuit 1208 is turned off, as shown by a large “X” (e.g., indicating current I1=0). For example, controller (e.g., controller 122 or 408) controls a phase shift angle CD between bridge circuits of the secondary-side circuits 1210 and 1212 for providing the AC excitation current signals I2 and I3 to the respective battery modules 1206a and 1206b during EIS. By controlling the phase shift between the secondary-side circuits 1210 and 1212, while the primary-side circuit 1208 is turned off, energy may be transferred between the secondary coils responsive to AC excitation current signals I2 and I3. Advantageously, because the AC excitation current signals I2 and I3 use only energy from the battery pack 1206 for performing EIS, EIS does not affect energy on the bus 1204. As a result, EIS may be performed on one or more battery packs of the ESS independently of battery management functions (e.g., APB, cell balancing, etc.) that may be performed for other battery packs.

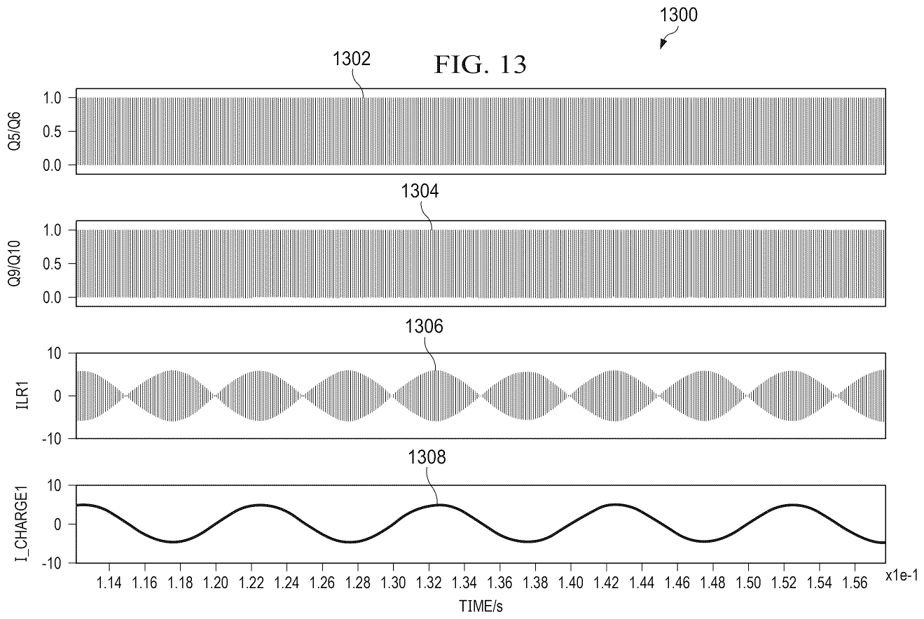

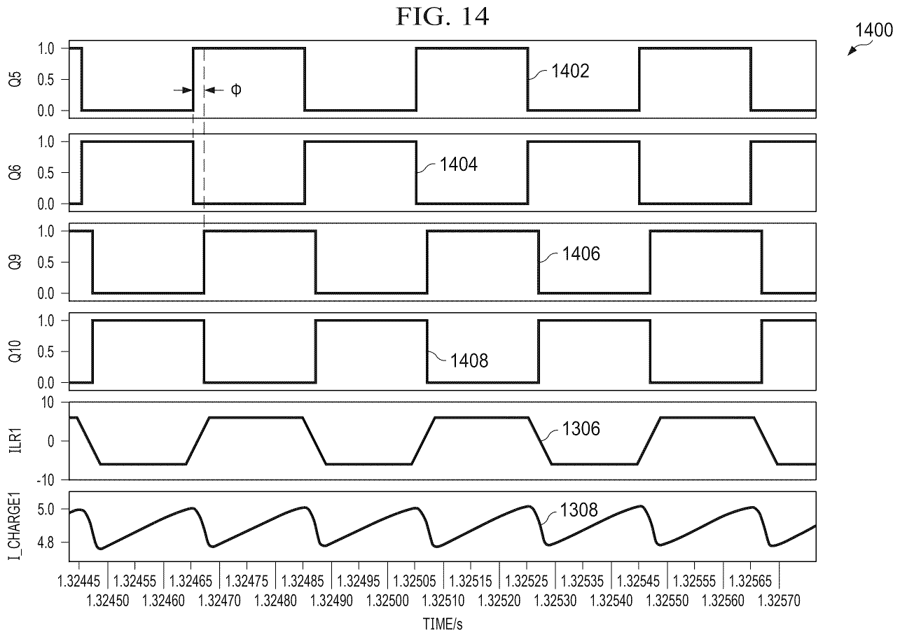

As a further example, FIGS. 13 and 14 are signal diagrams 1300 and 1400 showing examples of waveforms in the DC-DC converter of FIG. 4 that may be provided for performing EIS. The signal diagram 1300 depicts control signals 1302 provided to gates of FETs Q5/Q6, and control signals 1304 provided to gates of FETs Q9/Q10. The signal diagram 1300 also depicts a resonant current signal 1306 for current ILR1 through inductor LR1 and an AC excitation current signal 1308 for current signal I_CHARGE1 that is provided to the battery terminal 438 of the battery pack 406. As shown in FIG. 13, the AC excitation current signal 1308 is a sinusoidal waveform having an amplitude of 5 A. Due to the time scale of FIG. 13 and frequency of the signals, the control signals 1302 and 1304 and the resonant current signal 1306 appear saturated due to density of closely spaced lines in each of the waveforms.

Accordingly, FIG. 14 shows signal diagram 1400 for a zoomed-in portion of the signal diagram 1300 when the AC excitation current signal 1308 (I_CHARGE1) is near a peak of its positive cycle. As shown in the zoomed-in view of the AC excitation current signal 1308, the signal exhibits minor ripple due to the switching operation of FETS (e.g., Q5-Q11) of the full bridges in the secondary-side circuits 412 and 414. The signal diagram 1400 also shows separate control signals for FETs Q5, Q6, Q9, and Q10, shown at 1402, 1404, 1406, and 1408, respectively, as well as the resonant current signal 1306. As shown in FIG. 14, a phase offset, shown at D, is provided between FETs Q5 and Q9 as well as between FETs Q6 and Q10. A similar phase offset (not shown) exists between FETS Q8 and Q12 and FETs Q7 and Q11. By controlling the bridges (e.g., fully bridges) of the secondary-side circuits 412 and 414 with such offset, the AC excitation current signal 1308 may be provided with desired parameters for performing EIS on the battery cells of the battery pack 406 through transferring energy directly between the secondary-side circuits (see, e.g., FIG. 12). For example, a controller (e.g., controllers 122/408) can implement a closed loop in which the AC excitation current I_CHARGE1 is compared against a sinusoidal reference current, and the phase offset Φ can be set to minimize the difference between the AC excitation current I_CHARGE1 and the sinusoidal reference current. The frequency of the sinusoidal reference current can be varied to produce AC excitation current of different frequencies.

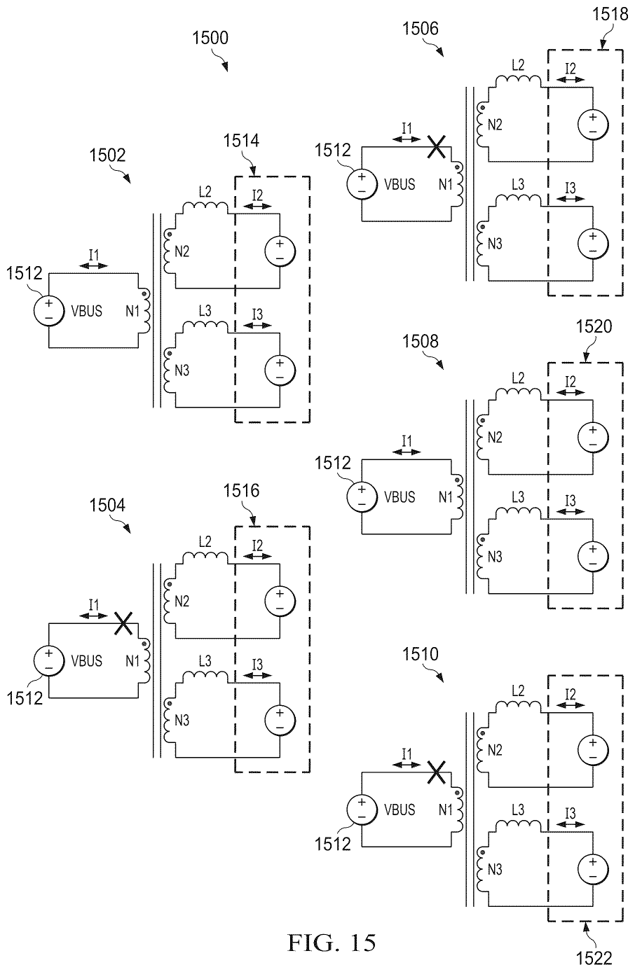

FIG. 15 is a schematic diagram of an ESS 1500 that includes a plurality of bidirectional isolated DC-DC converters 1502, 1504, 1506, 1508, and 1510 showing a combination of APB and EIS being performed for different battery packs. The ESS 1500 depicts simplified examples of DC-DC converters as provided in FIGS. 7 and 12, in which each isolated DC-DC converter 1502, 1504, 1506, 1508, and 1510 is coupled between a bus 1512, e.g., a voltage bus having bus voltage VBUS, and a respective battery pack 1514, 1516, 1518, 1520, and 1522. Other numbers and/or different configurations of DC-DC converters are possible for performing APB and EIS, as disclosed herein.

As shown in FIG. 15, isolated DC-DC converters 1502 and 1508 are being controlled (e.g., by controller 122, 408) to perform APB. In a first example, in response to determining that the voltage of the battery pack 1520 is greater than the battery pack 1514, APB includes controlling the isolated DC-DC converter 1508 to discharge battery pack 1520 by transferring energy from a secondary-side circuit(s) to the primary-side circuit and providing a substantially constant voltage to the bus 1512. In the first example the isolated DC-DC converter 1502 is further controlled to charge the battery pack 1514 by controlling the primary-side circuit thereof to transfer energy from the bus 1512 to one or more secondary-side circuits that provide substantially constant current to the battery pack 1514. Alternatively, in a second example, in response to determining that the voltage of the battery pack 1514 is greater than the battery pack 1520, APB includes controlling the isolated DC-DC converter 1502 to discharge battery pack 1514 by transferring energy from a secondary-side circuit(s) to the primary-side circuit and providing a substantially constant voltage to the bus 1512. The isolated DC-DC converter 1508 is controlled to charge the battery pack 1520 by controlling the primary-side circuit thereof to transfer energy from the bus 1512 to one or more secondary-side circuits that provide substantially constant current to the battery pack 1520. In some examples, EIS can be performed on the battery cells of battery packs 1514 and 1520 during the APB operation, where voltage and current across one or more battery cells of battery packs 1514/1520 are measured to determine the electrical impedance of the battery cells.

Also, in the example of FIG. 15, each of the isolated DC-DC converters 1504, 1506, and 1510 are controlled (e.g., by controller 122, 408) to perform EIS within a battery pack. Each of the isolated DC-DC converters 1504, 1506, and 1510 provides an AC excitation current signal to cells of the respective battery pack 1516, 1518, and 1522, concurrently or sequentially, as described with respect to the DC-DC converter 1202 of FIG. 12.

FIG. 16 depicts an example measurement system 1600 that includes a voltage sensing circuit 1602 and a current sensing circuit 1604, such as for providing voltage and current measurements for performing EIS in an ESS (e.g., ESS 100, 200, 400, 700, 1200, and 1500). The voltage sensing circuit 1602 is one possible example for implementing the voltage measurement circuits 460, and the current sensing circuit 1604 is one possible example for implementing the current monitor circuits 462. While one voltage sensing circuit is shown in FIG. 16, the measurement system 1600 may include a separate voltage sensing circuit 1602 for each battery cell, such as disclosed herein. Alternatively, one voltage sensing circuit 1602 may be coupled to respective battery cells through suitable interconnects to enable measuring of cell voltages in a multiplexed manner.

As shown in FIG. 16, the voltage sensing circuit 1602 includes inputs 1606 and 1608 coupled to terminals of a battery cell 1610. The battery cell 1610 along with one or more other battery cells 1612 may define battery module 1614. The battery cells 1610 and 1612 of the battery module 1614 are coupled in series between battery terminals 1616 and 1618. The battery module 1614 includes a portion of battery cells that form a battery pack.

The voltage sensing circuit 1602 includes an analog front end 1620 that includes an amplifier 1622 and an analog-to-digital converter (ADC) 1624. The inputs 1606 and 1608 are coupled to inputs of the amplifier 1622. Additional or different components are possible for implementing the analog front end 1620. The amplifier 1622 amplifies a voltage signal across the battery cell 1610 and provides the amplified voltage signal to the ADC 1624. The ADC 1624 converts the amplified voltage signal to a digital output signal, shown as V(n). The voltage sensing circuit 1602 performs digital processing of V(n) to provide a respective digital signal, shown as V(k), representative of the measured cell voltage. As one example, the digital processing of V(n) includes down sampling 1626, amplitude compensation 1628, filtering (e.g., shown as high-pass filtering) 1630, DC compensation 1632, a windowing function 1634, and a discrete Fourier transform (DFT) 1636 to provide the digital signal V(k) to an input of a controller 1640 (e.g., controller 122, 408) for additional processing. Other types of processing for the voltage sensing circuit 1602 are possible. For example, the controller 1640 calculates electrical impedance or impedance spectra based on the digital signal V(k) and a digital current signal I(k).

The digital current signal I(k) is provided by the current sensing circuit 1604. For example, the current sensing circuit 1604 includes an analog front end 1642 having inputs 1644 and 1646 coupled across a sense resistor RS coupled in series with the battery cells 1610 and 1612, such as in a return path to a respective DC-DC converter. The analog front end 1642 includes an ADC 1648 having inputs coupled to the inputs 1644 and 1646 for receiving a voltage signal (e.g., a voltage across RS), which is representative of the current through the battery cells. The ADC 1648 converts the amplified voltage signal to a digital output signal, shown as I(n). The current sensing circuit 1604 performs digital processing of I(n) to provide the digital current signal I(k), representative of the measured cell current. For example, the digital processing of I(n) includes down sampling 1650, amplitude compensation 1652, filtering (e.g., shown as high-pass filtering) 1654, DC compensation 1656, a windowing function 1658, and a discrete Fourier transform (DFT) 1660 to provide the digital signal I(k) to the controller 1640. Other types of digital processing for the current sensing circuit 1604 are possible. The controller 1640 calculates electrical impedance or impedance spectra based on the V(k) and I(k).

### Example Embodiments

Several aspects of the present technology are set forth in the following numbered examples.

Example 1. A system comprising:
a bus;
a primary coil;
a first circuit coupled between the bus and the primary coil;
a first secondary coil, in which the first secondary coil is DC-isolated from the primary coil;
a second secondary coil, in which the second secondary coil is DC-isolated from the primary coil;
first battery terminals;
second battery terminals;
a second circuit coupled between the first secondary coil and the first battery terminals;
a third circuit coupled between the second secondary coil and the second battery terminals; and
a controller coupled to the first circuit, the second circuit, and the third circuit, the controller being configurable to control at least two of the first circuit, the second circuit, and the third circuit to transfer energy either from the first secondary coil to the primary coil and then from the primary coil to the second secondary coil, or from the first secondary coil directly to the second secondary coil.

Example 2. The system of example 1, further comprising a bidirectional isolated DC-DC converter that includes the first circuit, the primary coil, the first secondary coil, the second secondary coil, the second circuit, and the third circuit, wherein each of the first secondary coil and the second secondary coil is magnetically coupled to the primary coil and to each other.

Example 3. The system of example 2, wherein the controller is configurable to control a phase shift between the second circuit and the third circuit to induce a voltage at the second secondary coil via the magnetic coupling between the first secondary coil and the second secondary coil, and to provide an excitation current signal to the second battery terminals responsive to the voltage induced at the second secondary coil.

Example 4. The system of example 3, wherein the controller is configurable to vary the phase shift responsive to a comparison between the excitation current signal and a sinusoidal reference current.

Example 5. The system of example 4, further comprising a plurality of battery cells coupled in series between the second battery terminals.

Example 6. The system of example 4, further comprising a battery pack that includes a first plurality of battery cells coupled between the first battery terminals and a second plurality of battery cells coupled between the second battery terminals.

Example 7. The system of example 6, wherein the controller is configurable to control the second circuit, based on a voltage of the first plurality of battery cells, to provide a respective signal through the first secondary coil to induce the voltage at the second secondary coil.

Example 8. The system of example 7, wherein the controller is configurable to turn off the first circuit when the excitation current signal is being provided.

Example 9. The system of any of examples 2 through 8, wherein the bidirectional isolated DC-DC converter is a first bidirectional isolated DC-DC converter, the system further comprising:
a first battery pack comprising first battery cells coupled between the first battery terminals and second battery cells coupled between the second battery terminals;
a second battery pack comprising third battery cells coupled between third battery terminals and fourth battery cells coupled between fourth battery terminals;
a second bidirectional isolated DC-DC converter coupled between the bus and the second battery pack, the second bidirectional isolated DC-DC converter comprising:
   a second primary coil;
   a fourth circuit coupled between the bus and the second primary coil;
   a third secondary coil magnetically coupled to the second primary coil;
   a fourth secondary coil magnetically coupled to the second primary coil and the third secondary coil;
   a fifth circuit coupled between the third secondary coil and the third battery terminals; and
   a sixth circuit coupled between the second secondary coil and the fourth battery terminals,
      wherein the controller is coupled to the fourth circuit, the fifth circuit, and the sixth circuit and configurable to control each of the first bidirectional isolated DC-DC converter and the second bidirectional isolated DC-DC converter in an electrochemical impedance spectroscopy mode and/or an active pack balancing mode.

Example 10. The system of any of the preceding examples, further comprising:
a plurality of battery cells coupled between the second battery terminals, wherein the controller is configurable to control the third circuit to provide an alternating-current (AC) excitation current signal to the plurality of battery cells coupled between second battery terminals; and
a measurement circuit coupled to at least one battery cell of the plurality of battery cells and configurable to measure a voltage of the at least one battery cell based on the AC excitation current signal, wherein the controller is coupled to the measurement circuit and configurable to determine an electrical impedance of the at least one battery cell based on the voltage of the at least one battery cell and the AC excitation current signal.

Example 11. The system of any of the preceding examples, wherein the first circuit comprises a first bridge circuit, the second circuit comprises a second bridge circuit, and the third circuit comprises a third bridge circuit.

Example 12. A system, comprising:
a bus;
a bidirectional isolated DC-DC converter, comprising:
   a primary coil;
   a first circuit coupled between the bus and the primary coil;
   a first secondary coil magnetically coupled to the primary coil;
   a second secondary coil magnetically coupled to the primary coil and the first secondary coil;
   a second circuit coupled between the first secondary coil and first and second battery terminals; and
   a third circuit coupled between the second secondary coil and third and fourth battery terminals;
      an energy storage element, comprising a plurality of battery cells, a first portion of the plurality of battery cells coupled between the first and second battery terminals and a second portion of the plurality of battery cells coupled between the third and fourth battery terminals; and
      a controller coupled to the bidirectional isolated DC-DC converter and configurable to control the bidirectional isolated converter to provide an alternating-current (AC) excitation current signal to the plurality of battery cells based on a voltage induced on at least one of the first secondary coil and the second secondary coil.

Example 13. The system of example 12, wherein the controller is configurable to control at least one of the second circuit and the third circuit to induce the voltage on at least one of the first secondary coil and the second secondary coil via the magnetic coupling between the first secondary coil and the second secondary coil.

Example 14. The system of example 12 or 13, wherein the controller is configurable to control the second circuit, based on a voltage between the first and second battery terminals, to transfer energy from the first portion of the plurality of battery cells to the third circuit, via the magnetic coupling between the first secondary coil and the second secondary coil, and control the third circuit to provide the AC excitation current signal to the second portion of the plurality of battery cells between the third and fourth battery terminals.

Example 15. The system of example 14, wherein the controller is configurable to turn off the first circuit when the AC excitation current signal is being provided.

Example 16. The system of any of examples 12-15, wherein the controller is configurable to control the bidirectional isolated converter to transfer energy either from the first secondary coil to the primary coil and then from the primary coil to the second secondary coil, or from the first secondary coil directly to the second secondary coil.

Example 17. The system of any of examples 12-16, wherein the first circuit comprises a first bridge circuit, the second circuit comprises a second bridge circuit, and the third circuit comprises a third bridge circuit.

Example 18. The system of any of examples 12-17, further comprising:
a measurement circuit coupled to at least one battery cell of the energy storage element and configurable to measure a voltage of the at least one battery cell based on the AC excitation current signal, wherein the controller is coupled to the measurement circuit and configurable to determine an electrical impedance of the at least one battery cell based on the voltage of the at least one battery cell and the AC excitation current signal.

Example 19. A method, comprising:
inducing a voltage at a secondary coil of a bidirectional isolated DC-DC converter;
providing, by the secondary coil responsive to the induced voltage, an excitation current to a battery pack coupled to the secondary coil;
measuring a voltage of at least one battery cell of the battery pack responsive to the excitation current;
measuring the excitation current; and
determining an electrical impedance of the at least one battery cell responsive to measuring the voltage and measuring the excitation current.

Example 20. The method of example 19, wherein the secondary coil is a first secondary coil of the bidirectional isolated DC-DC converter, the bidirectional isolated DC-DC converter including a second secondary coil, and the induction of the voltage is by magnetic coupling between the first and second secondary coils.

Example 21. The method of example 20, wherein the first secondary coil is coupled to a first battery cell of a battery pack, and the second coil is coupled to a second battery cell of the battery pack.

Example 22. The method of any of examples 19-21, wherein the bidirectional isolated DC-DC converter includes a primary coil coupled to a bus, and the induction of the voltage is by magnetic coupling between the primary coil and the secondary coil.

It should be understood that various aspects described herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this description are described as being performed by a single module or unit for purposes of clarity, it should be understood that the techniques of this description may be performed by a combination of units or modules.

In one or more examples, the described techniques may be implemented in hardware, software, firmware, or any combination thereof. If implemented in software, the functions may be stored as one or more instructions or code on a computer-readable medium and executed by a hardware-based processing unit. Computer-readable media may include non-transitory computer-readable media, which corresponds to a tangible medium such as data storage media (e.g., RAM, ROM, EEPROM, flash memory, or any other medium that can be used to store desired program code in the form of instructions or data structures and that can be accessed by a processor). For example, instructions may be executed by one or more processors, such as one or more digital signal processors (DSPs), general purpose microprocessors, application specific integrated circuits (ASICs), field programmable logic arrays (FPGAs), or other equivalent integrated or discrete logic circuitry. Accordingly, the term “processor” as used herein may refer to any of the foregoing structure(s) or any other physical structure suitable for implementation of the described techniques. Also, the techniques could be fully implemented in one or more circuits or logic elements.

In this description, numerical designations “first,” “second,” etc. are not necessarily consistent with same designations in the claims herein and these numerical designations are used to simply distinguish one element from another.

Additionally, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the term “circuit” can include a collection of active and/or passive elements that perform a circuit function, such as an analog circuit or digital circuit. Additionally, or alternatively, for example, the term “circuit” can include an IC where all or some of the circuit elements are fabricated on a common substrate (e.g., semiconductor substrate, such as a die or chip), such as disclosed herein.

In this description, a device that is “configured to” or “configurable to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means based at least in part on. Therefore, if X is based on Y, X can be a function of Y and any number of other factors. Also, as used herein, the term “includes” means includes but not limited to, and the term “including” means including but not limited to.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A system comprising:
a bus;
a primary coil;
a first circuit coupled between the bus and the primary coil;
a first secondary coil, in which the first secondary coil is DC-isolated from the primary coil;
a second secondary coil, in which the second secondary coil is DC-isolated from the primary coil;
first battery terminals;
second battery terminals;
a second circuit coupled between the first secondary coil and the first battery terminals;
a third circuit coupled between the second secondary coil and the second battery terminals; and
a controller coupled to the first circuit, the second circuit, and the third circuit, the controller being configurable to control at least two of the first circuit, the second circuit, and the third circuit to transfer energy either from the first secondary coil to the primary coil and then from the primary coil to the second secondary coil, or from the first secondary coil directly to the second secondary coil.

2. The system of claim 1, further comprising a bidirectional isolated DC-DC converter that includes the first circuit, the primary coil, the first secondary coil, the second secondary coil, the second circuit, and the third circuit, wherein each of the first secondary coil and the second secondary coil is magnetically coupled to the primary coil and to each other.

3. The system of claim 2, wherein the controller is configurable to control a phase shift between the second circuit and the third circuit to induce a voltage at the second secondary coil via the magnetic coupling between the first secondary coil and the second secondary coil, and to provide an excitation current signal to the second battery terminals responsive to the voltage induced at the second secondary coil.

4. The system of claim 3, wherein the controller is configurable to vary the phase shift responsive to a comparison between the excitation current signal and a sinusoidal reference current.

5. The system of claim 4, further comprising a plurality of battery cells coupled in series between the second battery terminals.

6. The system of claim 4, further comprising a battery pack that includes a first plurality of battery cells coupled between the first battery terminals and a second plurality of battery cells coupled between the second battery terminals.

7. The system of claim 6, wherein the controller is configurable to control the second circuit, based on a voltage of the first plurality of battery cells, to provide a respective signal through the first secondary coil to induce the voltage at the second secondary coil.

8. The system of claim 7, wherein the controller is configurable to turn off the first circuit when the excitation current signal is being provided.

9. The system of claim 2, wherein the bidirectional isolated DC-DC converter is a first bidirectional isolated DC-DC converter, the system further comprising:
a first battery pack comprising first battery cells coupled between the first battery terminals and second battery cells coupled between the second battery terminals;
a second battery pack comprising third battery cells coupled between third battery terminals and fourth battery cells coupled between fourth battery terminals;
a second bidirectional isolated DC-DC converter coupled between the bus and the second battery pack, the second bidirectional isolated DC-DC converter comprising:
a second primary coil;
a fourth circuit coupled between the bus and the second primary coil;
a third secondary coil magnetically coupled to the second primary coil;
a fourth secondary coil magnetically coupled to the second primary coil and the third secondary coil;
a fifth circuit coupled between the third secondary coil and the third battery terminals; and
a sixth circuit coupled between the second secondary coil and the fourth battery terminals,
wherein the controller is coupled to the fourth circuit, the fifth circuit, and the sixth circuit and configurable to control each of the first bidirectional isolated DC-DC converter and the second bidirectional isolated DC-DC converter in an electrochemical impedance spectroscopy mode and/or an active pack balancing mode.

10. The system of claim 1, further comprising:
a plurality of battery cells coupled between the second battery terminals, wherein the controller is configurable to control the third circuit to provide an alternating-current (AC) excitation current signal to the plurality of battery cells coupled between second battery terminals; and
a measurement circuit coupled to at least one battery cell of the plurality of battery cells and configurable to measure a voltage of the at least one battery cell based on the AC excitation current signal, wherein the controller is coupled to the measurement circuit and configurable to determine an electrical impedance of the at least one battery cell based on the voltage of the at least one battery cell and the AC excitation current signal.

11. The system of claim 1, wherein the first circuit comprises a first bridge circuit, the second circuit comprises a second bridge circuit, and the third circuit comprises a third bridge circuit.

12. A system, comprising:
a bus;
a bidirectional isolated DC-DC converter, comprising:
a primary coil;
a first circuit coupled between the bus and the primary coil;
a first secondary coil magnetically coupled to the primary coil;
a second secondary coil magnetically coupled to the primary coil and the first secondary coil;
a second circuit coupled between the first secondary coil and first and second battery terminals; and
a third circuit coupled between the second secondary coil and third and fourth battery terminals;
an energy storage element, comprising a plurality of battery cells, a first portion of the plurality of battery cells coupled between the first and second battery terminals and a second portion of the plurality of battery cells coupled between the third and fourth battery terminals; and
a controller coupled to the bidirectional isolated DC-DC converter and configurable to control the bidirectional isolated converter to provide an alternating-current (AC) excitation current signal to the plurality of battery cells based on a voltage induced on at least one of the first secondary coil and the second secondary coil.

13. The system of claim 12, wherein the controller is configurable to control at least one of the second circuit and the third circuit to induce the voltage on at least one of the first secondary coil and the second secondary coil via the magnetic coupling between the first secondary coil and the second secondary coil.

14. The system of claim 12, wherein the controller is configurable to control the second circuit, based on a voltage between the first and second battery terminals, to transfer energy from the first portion of the plurality of battery cells to the third circuit, via the magnetic coupling between the first secondary coil and the second secondary coil, and control the third circuit to provide the AC excitation current signal to the second portion of the plurality of battery cells between the third and fourth battery terminals.

15. The system of claim 14, wherein the controller is configurable to turn off the first circuit when the AC excitation current signal is being provided.

16. The system of claim 12, wherein the controller is configurable to control the bidirectional isolated converter to transfer energy either from the first secondary coil to the primary coil and then from the primary coil to the second secondary coil, or from the first secondary coil directly to the second secondary coil.

17. The system of claim 12, wherein the first circuit comprises a first bridge circuit, the second circuit comprises a second bridge circuit, and the third circuit comprises a third bridge circuit.

18. The system of claim 12, further comprising:
a measurement circuit coupled to at least one battery cell of the energy storage element and configurable to measure a voltage of the at least one battery cell based on the AC excitation current signal, wherein the controller is coupled to the measurement circuit and configurable to determine an electrical impedance of the at least one battery cell based on the voltage of the at least one battery cell and the AC excitation current signal.

19. A method, comprising:
inducing a voltage at a secondary coil of a bidirectional isolated DC-DC converter;
providing, by the secondary coil responsive to the induced voltage, an excitation current to a battery pack coupled to the secondary coil;
measuring a voltage of at least one battery cell of the battery pack responsive to the excitation current;
measuring the excitation current; and
determining an electrical impedance of the at least one battery cell responsive to measuring the voltage and measuring the excitation current.

20. The method of claim 19, wherein the secondary coil is a first secondary coil of the bidirectional isolated DC-DC converter, the bidirectional isolated DC-DC converter including a second secondary coil, and the induction of the voltage is by magnetic coupling between the first and second secondary coils.

21. The method of claim 20, wherein the first secondary coil is coupled to a first battery cell of a battery pack, and the second coil is coupled to a second battery cell of the battery pack.

22. The method of claim 19, wherein the bidirectional isolated DC-DC converter includes a primary coil coupled to a bus, and the induction of the voltage is by magnetic coupling between the primary coil and the secondary coil.
